(19) United States
(12) Patent Application Publication
(10) Pub. No.: US 2021/0101316 A1
(43) Pub. Date: Apr. 8, 2021

(54) NANOIMPRINTING BY USING SOFT MOLD AND RESIST SPREADING

(71) Applicant: NATIONAL CHENG KUNG UNIVERSITY, Tainan City (TW)

(72) Inventors: Yung-Chun LEE, Tainan City (TW); Yi-Chun TSAI, Tainan City (TW); Chun-Ying WU, Tainan City (TW); Wei-Hsiang SU, Tainan City (TW); Shao-Hsuan HUANG, Tainan City (TW); Ke-Chaung LU, Tainan City (TW)

(21) Appl. No.: 17/117,760

(22) Filed: Dec. 10, 2020

Related U.S. Application Data
(63) Continuation-in-part of application No. 15/685,793, filed on Aug. 24, 2017, now abandoned.
(60) Provisional application No. 63/042,619, filed on Jun. 23, 2020.

(30) Foreign Application Priority Data
Aug. 25, 2016 (TW) 105127611

(51) Int. Cl. B29C 33/42; B29C 33/40; B29C 33/06; B81C 1/00; B29C 35/08

(52) U.S. Cl. CPC B29C 33/424; B29C 33/405; G03F 7/0002; B81C 1/0046; B29C 35/0805; B29C 33/06

(57) ABSTRACT

A flexible mold has a mold body having a nanoimprinting microstructure and is gradually thickened from its periphery to the middle. Also, a resist spreading nanoimprinting method that integrates a soft mold into a dovetailed meal ring and then deforms it to form a point contact with a substrate before an imprinting process is followed and then convert a loading force into a specific distributed contact pressure for driving the resist flow by using an elastomer cushion pad with a pre-designed convex surface.

### CROSS-REFERENCE OF THE INVENTION

The present invention is a Continuation-in-Part of U.S. Non-Provisional application Ser. No. 15/685,793, filed on Aug. 24, 2017. The present invention also claims the benefit of U.S. Provisional Application No. 63/042,619, filed on Jun. 23, 2020.

### BACKGROUND OF THE INVENTION

### 1. Field of the Invention

The present invention relates to a flexible mold with variable thickness, and also is related to a nanoimprinting method that features on imprinting a resist and spreading it from center to edge to fully cover a wafer substrate.

### 2. Description of the Prior Art

Nanoimprinting technique has been developed for 20 years to provide an alternative approach for micro/nano-fabrication. Nevertheless, there are still many momentous technique bottlenecks to be overcome. These bottlenecks mainly comprise: (1) production mode, cost and service life of the imprinting mold; (2) control on the thickness and uniformity of the imprinting residue layer in large area; (3) control on accuracy of repetitive or multi-layer alignment; (4) overall process yield and cost competitiveness etc.

The core concept of nanoimprinting technique is to substitute the complex optical lithography technique with simple mechanical mechanism that duplicates the micro/nano-structure with large area and small feature dimension. Hence, three elements involved in a nanoimprinting process are a mold (or a stamp), a resist material (usually a polymer), and a substrate, wherein the mold contains certain pre-fabricated surface micro/nano-structures being going to be negatively replicated into the resist material on top of a substrate. The core techniques of the nanoimprinting techniques include contact, pressure, formation, and stripping, and also may include both physical and chemical changes of resist material against temperature and light. The challenge for nanoimprinting technique is that it must use mechanical approach with the consideration of the dimensions of two poles: formed area with large dimension (4″, 6″, 8″), structural characteristic of small line width (μm, sub-μm and nm). One key issue is how to bring the mold into conformal contact with the substrate, to faithfully replicate surface profiles into the resist, to ensure overall integrity of replicated structures after demolding, and to obtain homogeneous and minimized residual layer thickness in the imprinted micro-nano-structures. The strength of nanoimprinting lies in its simplicity, straightforwardness, and capability to achieve small feature sizes, large patterning areas, high throughput, but using less sophisticated equipment and processes.

Observing from the present nanoimprinting system design and imprinting technique in academia and industry, it is surprised that mechanical control is lacked during all the pressing process, such as average pressure on the mold during pressing process allowing an average contact pressure between the mold and substrate. Additionally, during stripping, defect caused by sharp pressure release often creates the fracture of micro-structure. Thus, the process forming polymer resistance layer by the existed nanoimprinting machine design and imprinting technique has a limited and feeble ability on controlling the final residual layer. Indeed, it may be possibly one of the key bottlenecks for the nano-imprinting technique and its industrial applications.

Particularly, the rigidity of the mold and the substrate involved in nanoimprinting significantly affects how the nanoimprinting should be carried out and whether it is more likely to get good imprinting results. Since the majority of substrates under consideration are usually wafers or panels made of hard and brittle solids, it may be assumed that the substrate is rigid and is supported by a rigid foundation. On the other hand, the rigidity of imprinting molds can vary a lot from hard rigid ones, such as silicon and quart molds, to soft and flexible ones, such as polydimethylsiloxane (PDMS) molds. Another important issue in nanoimprinting is how the resist material is deployed on top of the substrate surface before imprinting. There are three known ways: (1) spin-coating to form a resist layer, (2) droplet injecting to form an array of small resist droplets, and (3) deploying a single large droplet of resist material for imprinting. Depending on the rigidity of imprinting mold and the deployment of resist material, there are a number of possible imprinting strategies as shown schematically in FIGS. 1A to 1I.

In FIGS. 1A to 1C, the mold 101 is considered to be fairly rigid and for all three kinds of resist 102 deploying methods it will be very challenging to carry out nanoimprinting because of air-bubble trapping issues, difficulties in first forming conformal contact between mold 101 and substrate 103 and then separating them, and the vulnerability to mold 101 damages during imprinting and demolding stages. That is why soft molds 101 or flexible molds 101 are becoming more dominate in nanoimprinting nowadays. Not to mention the advantage of being able to replicate multiple soft molds 101 from one single mother mold 101 and therefore significantly reducing the cost. Various imprinting strategies depend on the rigidity of imprinting mold 101 and the deployment of resist 102 material.

For a flexible imprinting mold 101, as shown in FIGS. 1D to 1I, one can first deform the mold 101 a little bit so that the imprinting process can start from a point or line contact between mold 101, resist 102, and substrate 103. It can then gradually extend the imprinted area by closing the gap between mold 101 and substrate 103 using externally exerted pressure force. In the meantime, excessive resists 102 can be squeezed out from the mold 101/substrate 103 interface to minimize the residual layer thickness. This type of imprinting movement is important and helpful for forming a conformal contact between mold 101 and substrate 103, ensuring faithful profile replication, avoiding air-bubble trapping, and minimizing residual layer thickness. The initial contact position can be either at the edge, as depicted in FIGS. 1D to 1F, or at the center of the mold 101, as shown in FIGS. 1G to 1I. During imprinting the resist 102 is flowing and squeezing laterally due to distributed contact pressure between mold 101 and substrate 103. In the cases shown in FIGS. 1D to 1F the resist 102 flow is from one side to the other across the whole mold 101/substrate 103, while in FIGS. 1G to 1I from the center to the edges along all radial directions.

Regardless of mold 101 rigidity and deployment of resist 102 materials, the resist 102 flow driven by contact pressure during the imprinting stage plays a critical role in nanoimprinting lithography. A lot of research works have been reported before but most of them were focusing on rigid molds 101 as depicted in FIGS. 1A to 1C. However, the schemes depicted in FIGS. 1D to 1I are inherently favorable for nanoimprinting since they provide the contact angle needed for resist 102 flow, avoid air bubble trapping, and have a better chance of conformal mold 101/substrate 103 contact. One example is the substrate 103 conformal imprint lithography (SCIL) which is basically belonged to the scheme shown in FIG. 1F. The contact angle between mold 101 and substrate 103 is even more, if not equally, important in the demolding process in which most of imprinting happen.

Accordingly, new types of molds, resist materials, imprinting method, and imprinting tools are continuously emerged to make nanoimprinting more applicable to industry.

### SUMMARY OF THE INVENTION

To solve the problems of above traditional technique, the invention provides a flexible mold with variable thickness capable of providing precise mechanical control during the nano-imprinting process for accurate transferring and distribution on the pressed polymer layer material, and also provides a flexible mold with variable thickness that can absorb the unevenness of the substrate, distribute the pressure uniformly and drive the polymer layer to flow controllably.

In this invention, the flexible mold with variable thickness of the present invention mainly comprises a mold body. The lower surface of the mold body is an imprinting face having a nano-imprinting micro-structure; the mold body is gradually thickened from its periphery to above the middle. Due to the larger thickness at the center of the mold body, a larger amount of compression may be produced to cause a larger contact pressure between the micro-structure at the bottom of the mold body and the imprinted object. As usual, the mold body is molded from a thermosetting silicone material.

Further, the invention provides a new type of nanoimprinting process and its imprinting tool to realize a resist spreading nanoimprinting process using a flexible mole. There are three key elements in the new imprinting system. First of all, a soft mold is integrated with a metal ring using standard molding and mold replication approaches. This allows the soft mold to be firmly clamped and fixed at its perimeter, and easily deformed by external forces or returned back to its original shape after removing external forces. Secondly, for a soft mold being fixed in space, there are two independent force loading either from the upper of the lower directions of the mold. Which makes it possible to form an initial point contact between a soft contact, a droplet or a layer of resist, and a substrate, and then carry out the imprinting process. Finally, a curved elastomer cushion pad with a pre-designed surface profile is used to continuously create a time-varying contact pressure distribution between mold and substrate. During the imprinting stage, the magnitude of this contact pressure is monotonically increasing but the spatial distribution of contact pressure always keeps a negative gradient toward the radial direction, which is important to drive the resist flow and maintain the imprinted residual layer thickness. Additionally, the spread resist is solidified by UV light or other ways so as to form the required micro/nano-structures.

Furthermore, the concept and the imprinting tool can be readily applied to a broad range of imprinting methods as long as the imprinting mold is slightly deformable. For example, before forming an initial contact to carry out imprinting, both a droplet of resist and a thin resist layer may be formed on a substrate. All the advantages including forming conformal contact, squeezing resist flow, preventing air bubble trapping, and maintaining minimized residual layer thickness are well preserved in this proposed imprinting approach no matter how the resist is placed on substrate before the formation of the initial contact. Most importantly, it can easily reverse the imprinting to ensure a successful demolding process. Besides UV nanoimprinting, the thermal or hot-embossing nanoimprinting also may be processed by simply adding a heat source to the substrate. Another strength of the proposed nanoimprinting system is its flexibility and adjustability. There are many parameters one can fin-tune to cope with different imprinting conditions such as the material properties of soft mold, the rheology of resist material, the characteristics of targeted profiles of imprinted mico/nano-structures, . . . etc. The main factors are the surface profile of the curved elastomer pad, the initial deflection of soft mold, the time-dependent advancing and retracting movement of both upper and lower frames during imprinting and demolding stages.

In particular, by adjusting how the soft mold is deformed during the period from the formation of the initial contact until the ending of the imprinting stage, and/or by adjusting at least the size, such as the depth, of the micro/nano-structure on the mold, the deformation degree of the mold after being pressed, and/or the thickness of the resist on the substrate before being mechanically interact with the mold, how the micro/nano-structure is transformed into the resist may be flexibly adjusted. That is to say, even the micro/nano-structure is distributed uniformly over the surface of the mold, the profile of the micro/nano-structure may be transformed non-uniformly into the resist, wherein the micro/nano-structure is fully inserted into the resist on the center portion of the substrate but is only partially inserted into the resist on the periphery/surrounding portion of the substrate. In other words, after the resist is cured, a micro/nano-structure with larger undulations in the middle and smaller surrounding undulations can be obtained.

### BRIEF DESCRIPTION OF THE DRAWINGS

With reference to the detailed descriptions and accompanying figures related with the present invention, the technical content and purpose effects of the present invention will be further understood:

FIGS. 1A to 1I present various imprinting strategies depending on the rigidity of imprinting mode and the deployment of resist material.

FIG. 2 is a side view of the flexible mold with variable thickness of the present invention;

FIG. 3 is a schematic view (1) of the use status for the flexible mold with variable thickness of the present invention;

FIG. 4 is a schematic view (2) of the use status for the flexible mold with variable thickness of the present invention;

FIG. 5 is a schematic view (3) of the use status for the flexible mold with variable thickness of the present invention;

FIG. 6 is a side view of another embodiment of the flexible mold with variable thickness of the present invention;

FIG. 7 is a schematic view (1) of the user status in another embodiment of the flexible mold with variable thickness of the present invention;

FIG. 8 is a schematic view (2) of the user status in another embodiment of the soft mold with variable thickness of the present invention.

FIGS. 9A to 9F show schematically the flow diagrams for a specific imprinting method.

FIGS. 10A to 10C show schematically the preparation of a soft PDMS mold by molding and thermally curing along with a metal ring with an inner dovetailed groove.

FIG. 11 is a photo of a prepared PDMS mold integrated with a dovetailed metal ring.

FIG. 12 shows schematically both structures and components of an exemplary system for carrying out the resist spreading nanoimprinting.

FIGS. 13A to 13F show schematically the resist spreading process carried out by the developed imprinting system.

FIG. 14 shows schematically a curved elastomer pad prepared by PDMS molding from a steel mold which has a designed and machined concave surface.

FIG. 15 shows the simulation results of several surface profiles of the curved elastomer pad using conic curves for the sag height function.

FIGS. 16A to 16C are several surface profiles of the curved elastomer pad using conic curves for the sag height function as the simulation results.

FIGS. 17A to 17C show experimentally measured distribution of contact pressure under different loading forces when using hyperbolic, parabolic, and elliptical sag functions in the design of a curved elastomer pad.

FIG. 18A shows a photo of the 4″ glass wafer with imprinted micro-pillars.

FIGS. 18B to 18C show two top view SEM images of imprinted SU8 micro-pillars respectively.

FIGS. 19A to 19E are cross-sectional SEM images of imprinted SU8 micro-pillars at five different locations indicated in FIG. 18A.

FIG. 20A shows schematically a photo of the imprinted glass wafer with arrayed nano-holes.

FIGS. 20B to 20C show two top view SEM images of imprinted mr-NIL-210 nano-holes.

FIGS. 21A to 21E are cross-sectional SEM images of imprinted nano-holes on the resist of mr-NIL 210 at five different locations indicted in FIG. 20A.

FIGS. 22A to 22D show schematically some steps of a specific embodiment.

FIGS. 23A to 23D show schematically some step of another specific embodiment.

### DETAILED DESCRIPTION OF THE PREFERRED EMBODIMENT

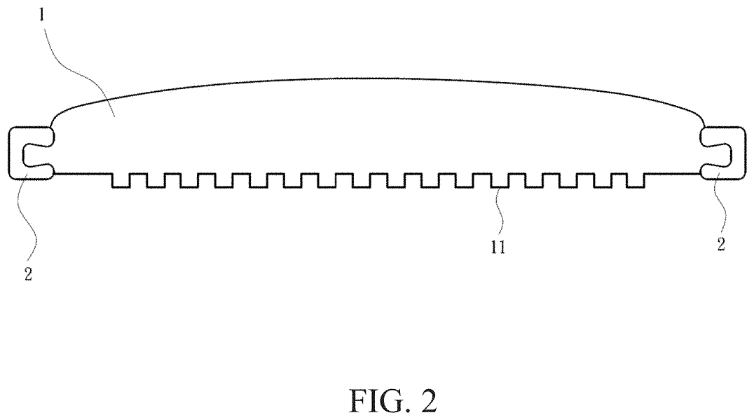

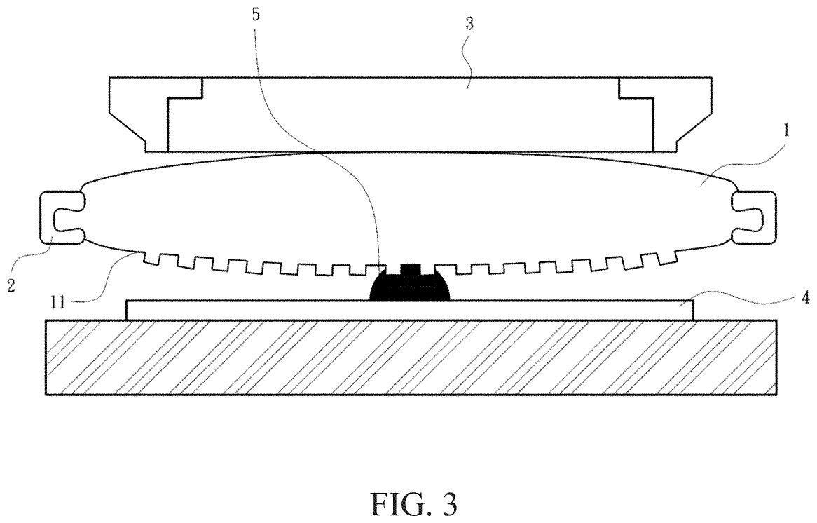

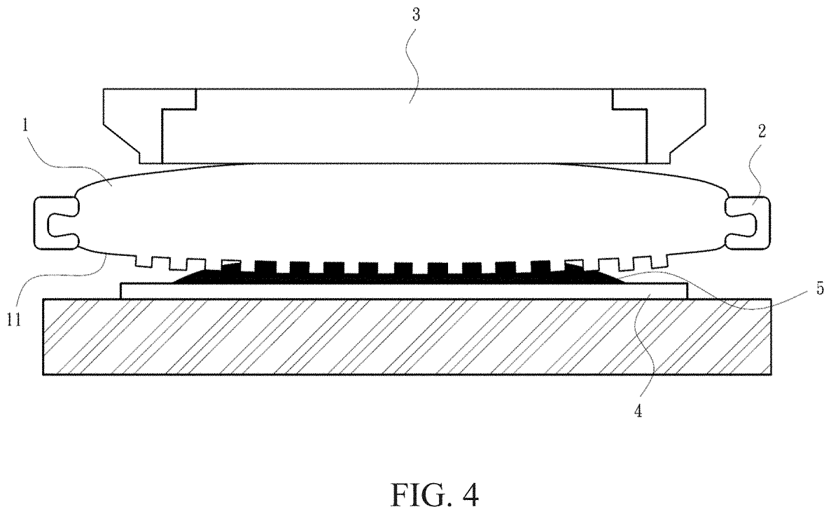

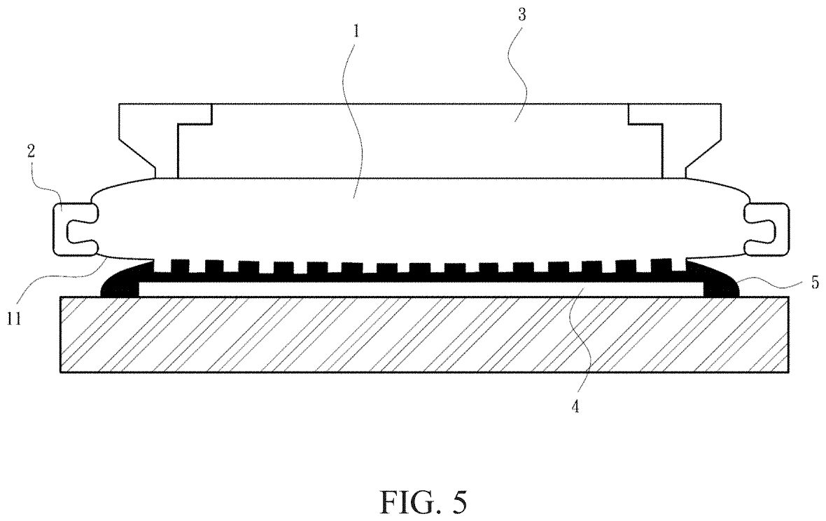

With reference to FIGS. 2-5, in the first embodiment of the flexible mold with variable thickness of the present invention, a mold body 1 of the flexible mold with variable thickness of the present invention is formed by combining a silicon crystal round mold having micro-structure with a stainless steel mold having curved surface and casting them with a thermosetting silicone material. The bottom of the mold body 1 is an imprinting face 11 having nano-imprinting micro-structure and the mold body 1 is thickened gradually from the periphery of the mold body 1 to above the middle.

The periphery of the mold body 1 of the flexible mold with variable thickness of the present invention is mainly secured by a metal ring 2, and then applying a force or displacement to the upper surface of the mold body 1 with a hard backplate 3 to cause the imprinting face 11 of the mold body 1 to deform and protrude, wherein the central area of the imprinting face 11 being in contact with a resist glue 5 on a substrate 4. Subsequently, the relative distance between the hard backplate and the substrate is further shortened, and since the mold body 1 has a large thickness at the center. It may produce a large amount of compression when being pressed by the hard backplate 3 and the substrate 4 to cause a larger contact pressure between the imprinting face 11 of the mold body 1 and the substrate 4, thus forcing the resist glue 5 to fill into the recess of the micro-structure and to extrude the redundant resist glue 5 to flow outward to the edge of the substrate 4. During the imprinting process, the distribution of contact pressure can be controlled by the approaching rate and displacement from the hard backplate 3 to the substrate 4. Then the resist glue is cured by UV radiation and/or heating to complete the nano-imprinting formation flow for the micro-structure. Finally, the draft angle and separation rate can be controlled by the rate and displacement of the hard backplate 3 away from the substrate 4, so that defect of the fracture of micro-structure caused by the sharp release in force can be avoided during stripping in traditional techniques.

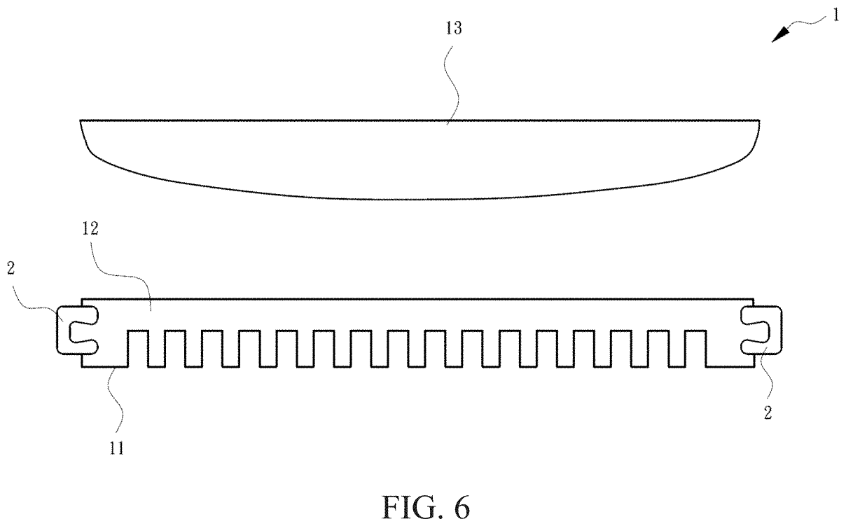

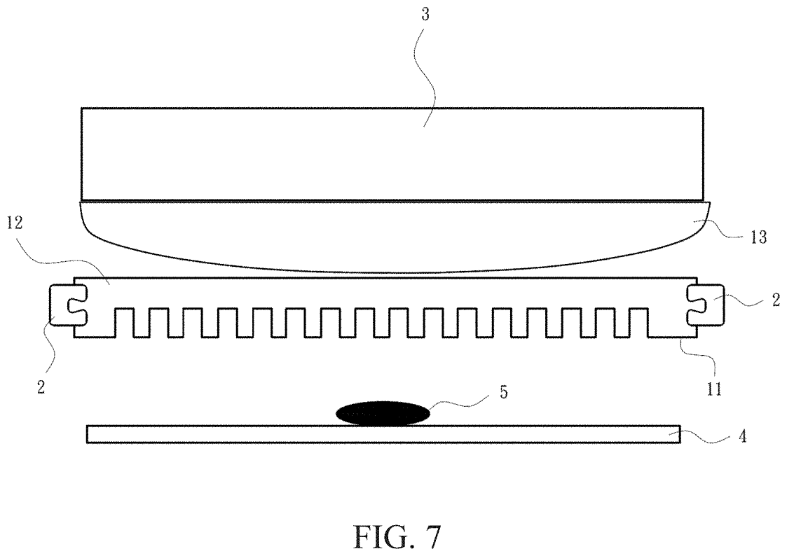

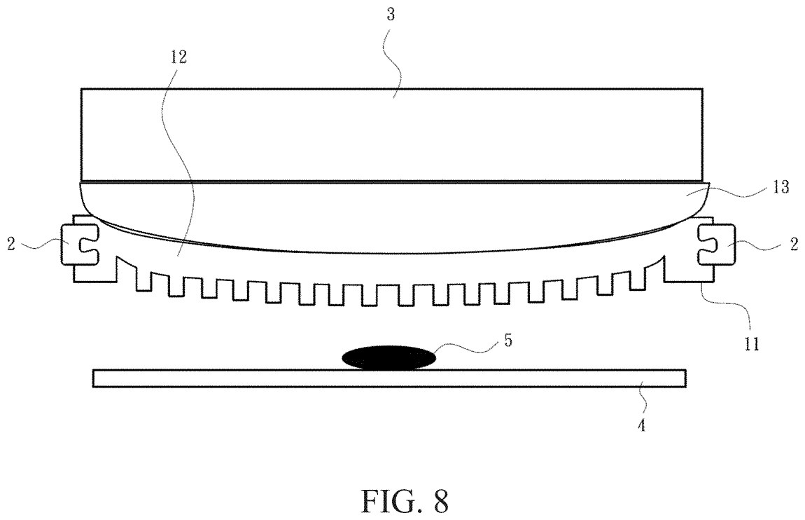

With reference to FIGS. 6-8, in the second embodiment of the flexible mold with variable thickness of the present invention, a mold body 1 of the flexible mold with variable thickness of the present invention includes an imprinting mold 12 and soft mold 13. The lower surface of the imprinting mold 12 is the imprinting face 11 having nano-imprinting micro-structure and the soft mold 13 is an elastomer thickened gradually from the periphery to the middle, and the soft mold 13 is gradually thickened from the periphery of the soft mold 13 to below the middle of the soft mold 13.

The present embodiment mainly uses the metal ring 2 to hold and fix the periphery of the imprinting mold 12, and then combing the soft mold 13 with the hard backplate 3 and applying a displacement or force onto the imprinting mold 12 to cause the imprinting face 11 of the imprinting mold 12 to deform and protrude. Thus, the central area of the imprinting face 11 contacting with the resist glue 5 on the substrate 4. Subsequently, the relative distance between the hard backplate 3 and the substrate 4 is further shortened, since the soft mold 13 has a large thickness at the center. It may produce a large amount of compression when the imprinting mold 12 is pressed to cause a larger contact pressure between the imprinting face 11 of the imprinting mold 13 and the substrate 4, thus forcing the resist glue 5 to fill into the recess of the micro-structure and to extrude the redundant resist glue 5 to flow outward to the edge of the substrate 4.

As described above, compared with traditional technique, the flexible mold with variable thickness of the present invention has following characteristics and effects:

1. The present invention forms a contact pressure distribution featured as strong in the center but weak around between the mold body and the substrate by the different stresses and strain produced upon deformation in the imprinting process through the thickness difference, forcing the resist glue to flow outward from the center of the substrate and thus achieving the purpose of uniform distribution while solving the drawback of wasting glue materials in tradition spin-coating process.

2. The present invention can control the deformation amount of the mold body by applying displacement or force onto the mold body during imprinting process through the thickness difference of the mold body, and further achieve the control on the contact pressure during the imprinting process, thus achieving the purposes of high uniformity of micro-structure resulted from imprinting and minimal thickness of the bottom residual layer.

3. The present invention controls the deformation amount of the mold body upon stripping by the thickness difference of the mold body to improve the fracture defect of micro-structure caused by excessive draft angle and sharp release of pressure.

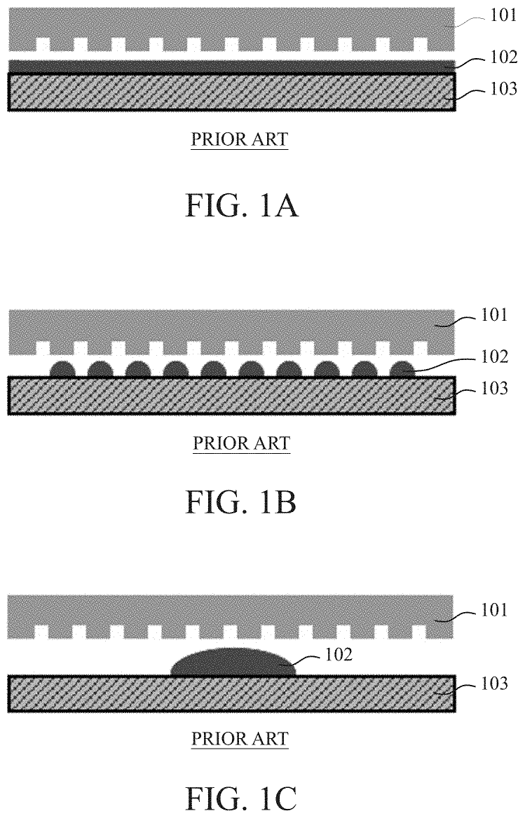

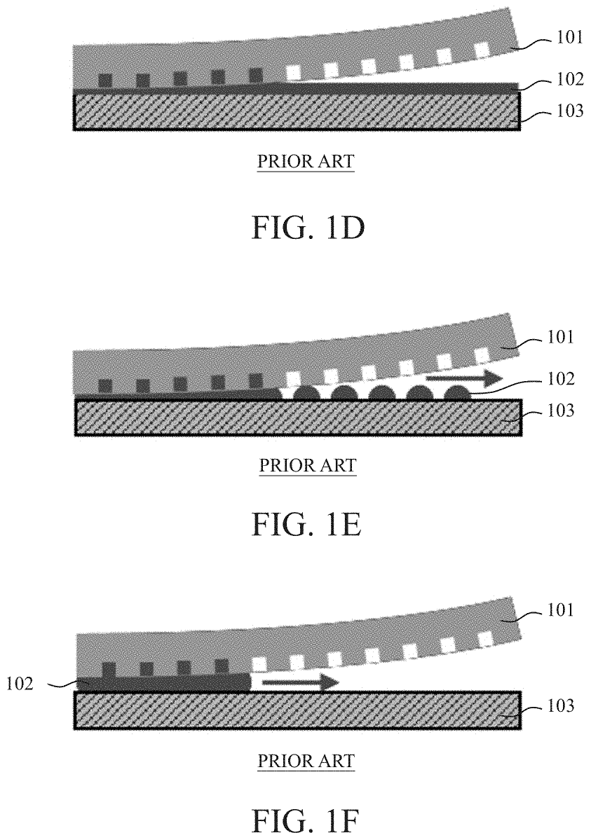

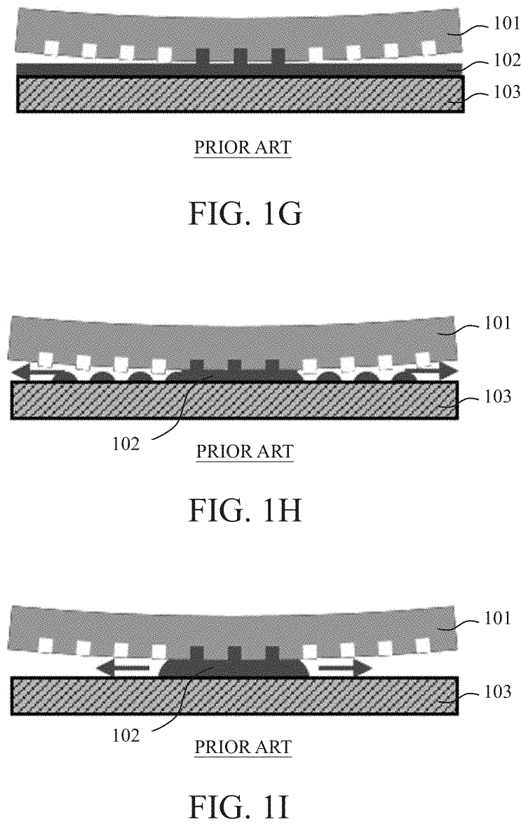

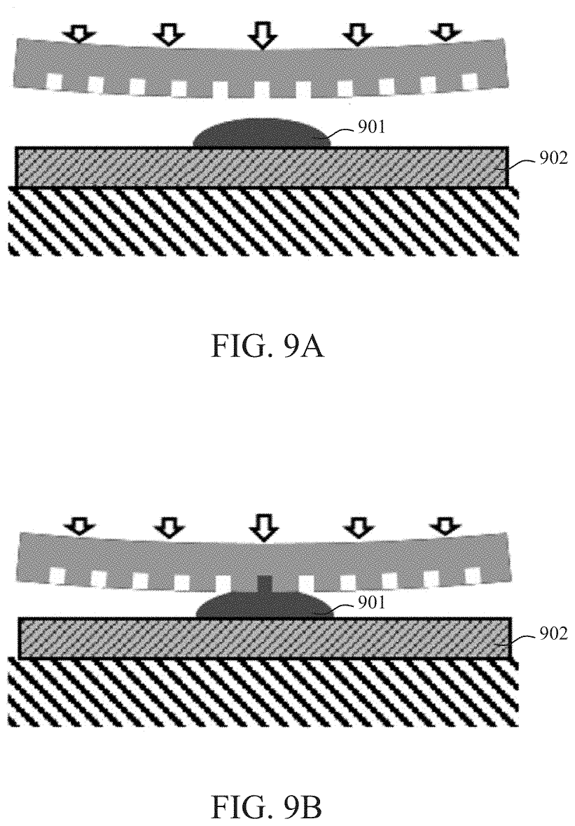

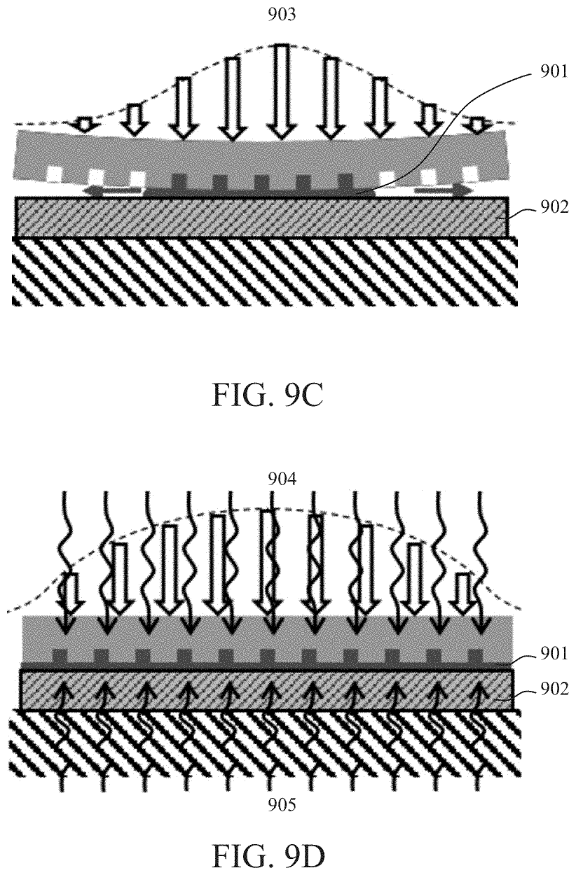

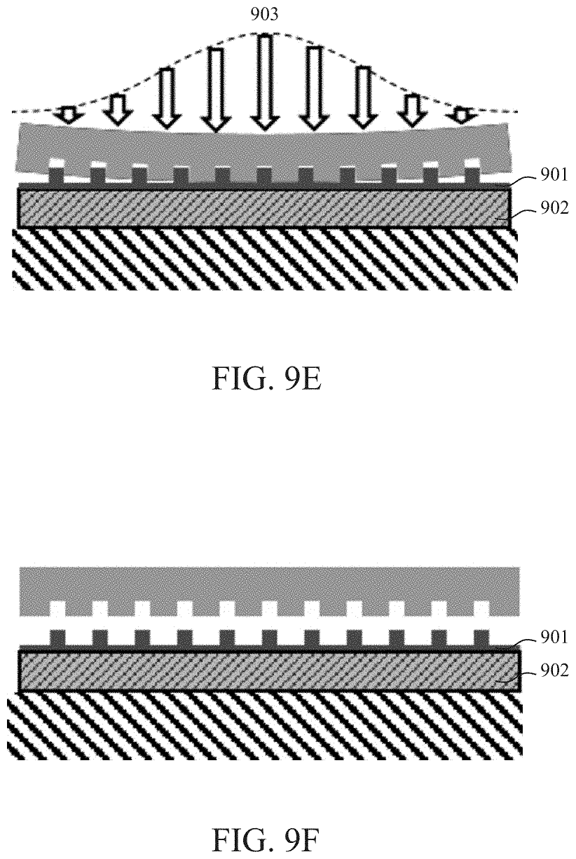

Furthermore, the invention mainly interests in and focuses on the imprinting method depicted in FIG. 1I, which is rarely discussed in the literature before. FIGS. 9A to 9F show schematically the flow diagrams for this specific imprinting method. It first leaves a single droplet of resist 901 at the center of the substrate 902 and slightly deforms the flexible mold into a spherically convex shape toward the substrate, as shown in FIG. 9A. Of course, a resist layer may be formed at the center of the substrate to replace the signal droplet of resist, if necessary. It then brings the mold closer to the substrate and forms an initial point contact with the resist droplet, as shown in FIG. 9B. After that, external forces are applied to the mold to imprint the resist as well as to squeeze the resist flow from center to edge, as shown in FIG. 9C, wherein a distributed pressure force 903 is illustrated. As shown in FIG. 9D, when the resist is completely imprinted by the mold, either ultraviolet (UV) radiation 904 or thermal heating 905 can be applied to solidify the resist layer. The next step is to reverse the imprinting process so that the mold can gradually separate from the substrate in a similar configuration. Preferably this demolding process starts from the edge and moves toward the center, as shown in FIG. 9E, to ensure the integrity of imprinted resist structures after demolding. Finally, after demolding, the imprinted micro/nano-structures can stay on top of the substrate with a minimum residual thickness, as shown in FIG. 9F.

There are many significant advantages in this proposed droplet spreading nanoimprinting method shown in FIGS. 9A to 9F. First of all, it is more likely to achieve successful results since the imprinting starts from a point contact in the center and gradually moves toward all radial directions. A properly controlled distribution of loading pressure can drive the resist flow and fill the cavities between mold and substrate without air-bubble trapping. Secondly, it can save the spin-coating process which may sometimes not applicable to certain substrates and/or resist materials. There is no need to worry about controlling the spin-coated film thickness for minimized residual layer thickness. It also significantly reduces the amount of resist material being used since more than 99% of them are wasted in spin-coating. Finally, the revered demolding process depicted in FIG. 9E is critically important to ensure the integrity of imprinted structures since most imprinting defects occur during the demolding process.

Sequentially, some embodiments of this invention are related to the imprinting system to carry out the proposed imprinting method shown in FIGS. 9A to 9F. Some embodiments are related to a novel way for preparing a soft mold, which makes the proposed imprinting processes become possible. Some embodiments are related to the imprinting machine equipped with all the functionalities described in FIGS. 9A to 9F. Also, some embodiments experimentally measure the distributed contact pressure step by step in the imprinting process by using this presented imprinting tool, and the nanoimprinting results obtained experimentally using this droplet spreading nanoimprinting system.

Some embodiments are related to the method for making a PDMS mold. In general, soft imprinting molds have been regularly and constantly prepared from a mother mold (usually a silicon mold) by standard molding process. There are a number of different materials used for soft imprinting molds, and among them, PDMS is the most common choice. There are a variety of PDMS materials one can choose depending on targeted feature sizes and desired flexibility. Typically, the mold processes start from mixing two liquid compounds into a PDMS solution and then degassing it. The PDMS solution is poured over the surface of the mother mold and then cured either by thermal heating or UV radiation. Before this molding process, the silicon mold surface is treated for anti-adhesion to ensure smooth demolding. A PDMS soft mold is then obtained after separating it from its mother mold. However, the flexibility of a soft mold is preferred for nanoimprinting, but on the other hand, it can also be a problem in mold handling. Unlike hard imprinting molds, soft molds will undergo large deformation even by its own weight. It is not so easy to properly mount them into an imprint system without changing its shape or dimensions. On some occasions, the prepared PDMS mold is adhering to a backing plate, but this not only increases the complexities in mold preparation but also affect the flexibility. Finally, typical PDMS materials undergo a volume shrinkage of few percent in its thermally curing process and hence induce some undesired structure deformation in the PDMS mold itself and in the replicated micro/nano-structures.

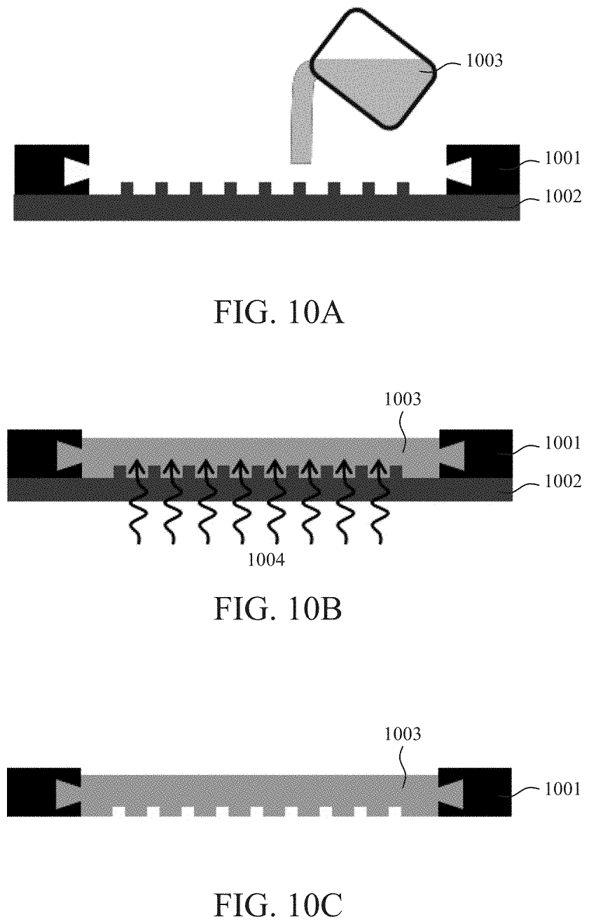

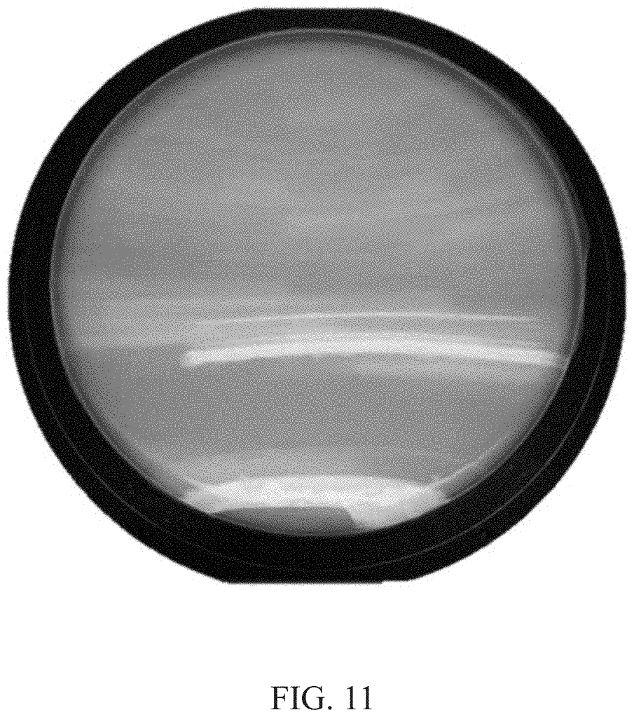

These embodiments are related to an innovative method for making a PDMS mold using standard molding processes but solving the mold handling issues simultaneously. As shown in FIG. 10A, the key feature in this new method is using a metal ring 1001 with a dovetailed groove inside its inner surface. The dovetailed groove can be machined by either a lathe or a milling machine with properly chosen cutters and cutting procedures. This dovetailed ring is then placed on top of the mother mold 1002, such as a silicon mod, and the PDMS solution 1003 is pouring into the cavity defined by the ring and the mother mold. Just for example, the PDMS molds used for imprinting can be made of PDMS 1001 (provided by Sylgard™, Dow Corning Co., MI, USA), which has a relatively higher rigidity than the commonly used PDMS 184 (provided by Sylgard™, Dow Corning Co., MI, USA). The PDMS elastomer and its curing agent are mixed with a volume ratio of 1:1, and then degassed and poured over a silicon mold for thermally curing. As shown in FIG. 10B, the liquid PDMS 1003 can fill the dovetailed groove and then solidified by thermally curing 1004. After separating from the mother mold 1002, the replicated soft PDMS mold is now embedded and firmly integrated into the dovetailed metal ring, as shown in FIG. 10C. This not only solves the mold handing issue but also allows the PDMS to be deformable easily, which plays a critical role in the proposed droplet spreading imprint processes. FIG. 11 is a photo of a so prepared soft PDMS mold and its dovetailed metal ring. The ring is made of aluminum alloy with the inner and outer diameters and thickness of 86 mm, 101 mm, and 9 mm, respectively. The thickness of the prepared PDMS mold is 7 mm which covers the whole dovetailed groove inside the metal ring.

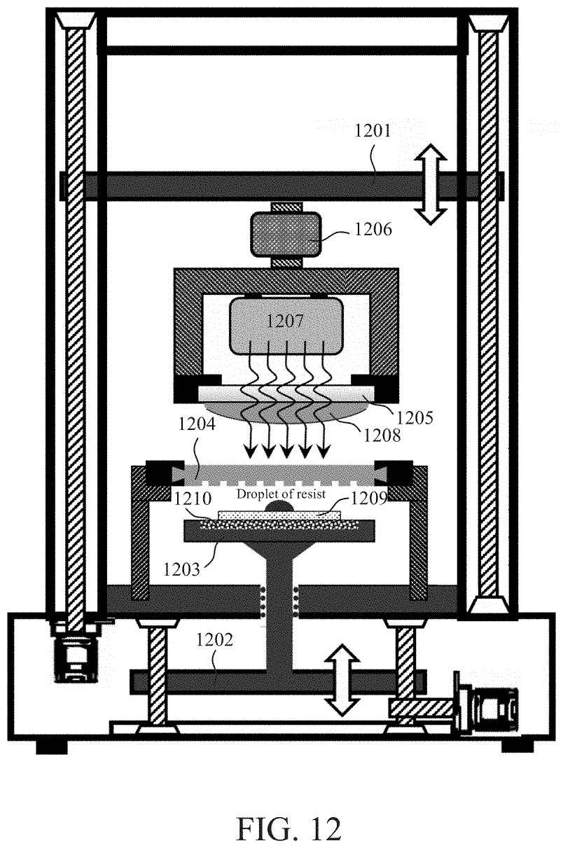

Some embodiments are related to an imprinting machine system for realizing the proposed resist spreading imprinting method. Just for example, FIG. 12 schematically shows an exemplary system design and important components adopted therein. This machine system is modified from and similar to a typical mechanical material testing system and is equipped with dual loading frames on top and bottom. As shown in FIG. 12, the upper and lower loading frames 1201/1202 are individually driven to be capable of moving upward and downward. Just for example, they may be driven by their corresponding motor/gear/screw systems and exert loading forces up to 1,000 kgf. Above the table 1203 in the machine, a soft PDMS mold 1204 is mounted with a holding fixture through its dovetailed metal ring. This soft PDMS mold 1204 is therefore firmly griped at its perimeter and fixed in space in the machine. Above the PDMS mold 1204, a thick quartz plate 1205 is held by a fixture which is then attached to the upper loading frame 1201 through a load cell 1206. Inside the holding fixture, there is a planar UV light source 1207 that can radiate UV light through the quartz plate 1205. An elastomer cushion pad 1208 with a convex surface profile is adhered to the quartz plate 1205. A substrate 1209 is placed on the table 1203 which is connected with the lower loading frame 1202 so that it can move vertically. The substrate 1209 is firmly adhered to a vacuum plate 1210 embedded in the table 1203. Moreover, a droplet of resist may be placed on the center of the substrate 1209 right beneath the PDMS mold 1208. The servo-controlled motion of upper and lower loading frames 1201/1202, the reading out of loading force from the load cell 1203, and the UV light source 1207 are all controlled by a personal computer (PC) which is not shown in FIG. 12.

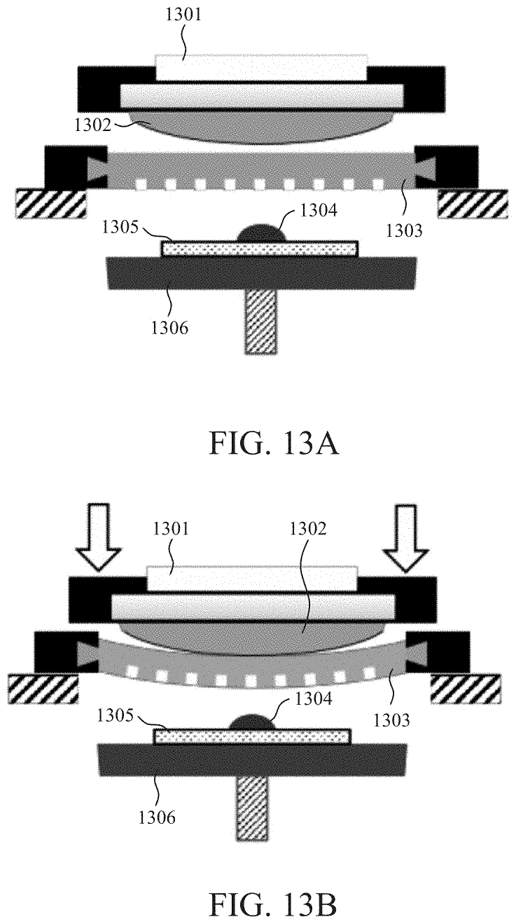

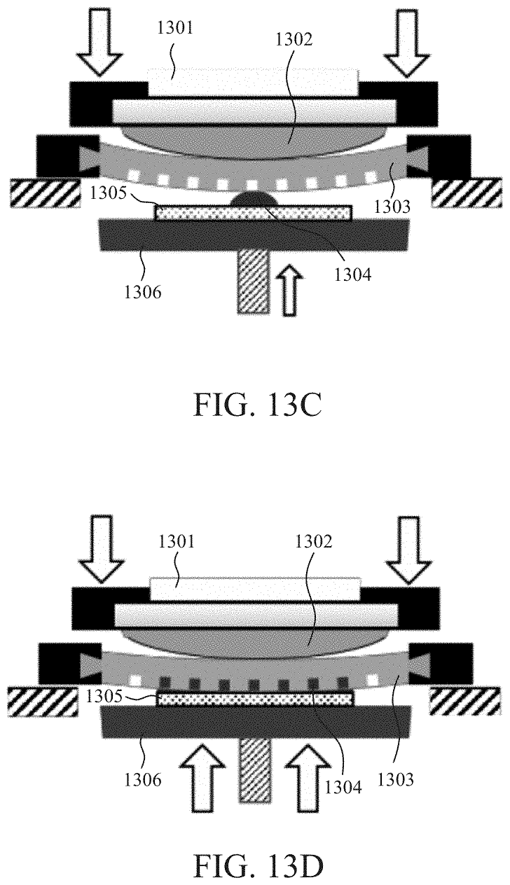

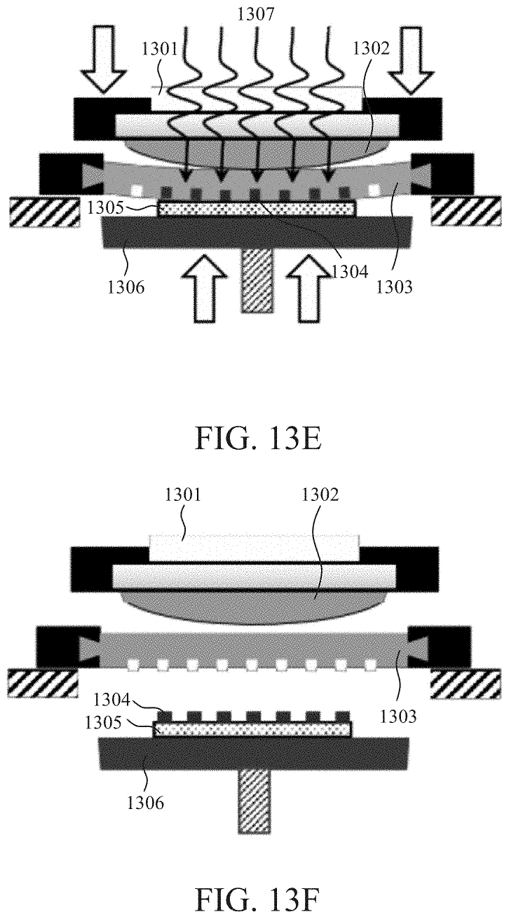

This established imprinting system can realize the proposed resist spreading nanoimprinting method and the whole processes are schematically shown in FIGS. 13A to 13F. FIG. 13A shows the initial positions of the quartz plate 1301, curved elastomer pad 1302, PDMS mold 1303, droplet of resist 1304, and substrate 1305. The upper loading frame (not shown) moves toward the PDMS mold 1303 first to slightly deform the PDMS mold 1303 downwardly, as shown in FIG. 13B. The lower loading frame 1306 and the substrate 1305 is then approaching the deformed PDMS mold 1303 until the droplet of resist 1304 forms an initial contact with the PDMD mold 1303 at its lowest point, as shown in FIG. 13C. After that, either one or both of the upper and lower loading frames 1306 can advance further to establish contact pressure between PDMS mold 1303 and substrate 1305. This externally applied pressure at the mold/substrate 1303/1305 interface will drive the resist flow, close the gap between mold 1303 and substrate 1305, enlarge contact area, and imprint mold's surface profiles into the layered resist 1304. This imprinting process begins from the center and radially moves toward the edge of the substrate 1305 along all radial directions. The speed of the imprinting process is controlled by the movement of either or both of loading frames non-shown/1306 with a pre-programmed time history in terms of displacement or velocity. The magnitude and distribution of the applied contact pressure are strongly determined by the thickness profile of the curved elastomer pad 1302 through its compressive deformation and stain during imprinting. Just for example, this elastomer pad 1302 can be made of PDMS 184 by its standard molding procedures using a steel mold with a pre-designed concave surface machined by a numerical control (NC) machine. Once the substrate 1305 is imprinted properly, such as whole of the substrate 1305 is imprinted, UV light 1307 is radiated through the quartz plate 1301, the elastomer PDMS pad 1302, and the metal-ring-embedded PDMS mold 1303 to solidify the imprinted resist 1304, as shown in FIGS. 13D to 13E. After curing the resist 1304, the imprinting movement can be reversed by withdrawing upper loading frame and/or lower loading frame 1306 away from the PDMS mold 1304. This will allow the demolding process to start from the edge and gradually move toward the central area with a contact angle until complete separation between mold 1303 and substrate 1305, as shown in FIG. 13F. Then, the imprinted substrate 1305 can be moved and turned back to FIG. 13A for a new cycle of imprinting.

Note that there are several adjustable factors for achieving better imprinting results when performing nanoimprinting processes as shown in FIGS. 13A to 13F. These factors include but not limited to the initial displacement of deformed PDMS mold, the thickness profile of the curved elastomer pad being used, the subsequent movements of both upper and lower loading frames during imprinting and demolding stages. As a matter of fact, the strength of the proposed imprinting method and its imprinting tool lies in the abundance of parameters and scenarios one can utilize to improve and optimize the imprinting results. One can easily edit the importing processes since the movements of loading frames are controlled by a PC, which also monitors the applied loading force through a load cell. As for the curved elastomer pad, it first allows the initial deformation of the PDMS mold and then creates a distributed compressive pressure at the mold/resist/substrate interface for squeezing the resist flow and for ensuring a faithful profile replication and a minimum residual layer thickness. The thickness profile of this curved elastomer pad and the time-history of loading frames' movements determine the distributed interfacial pressure at each time step.

It should be emphasized that the combination of the quartz plate and the UV light source is only an example, the invention does not limit how to solidify the resist. In another non-illustrated embodiment, the machine shown in FIG. 12 replaces the UV light source with a heat source, such as light bulbs or thermoelectric wires, even to replace the quartz plate with a plate made of other materials. That is to say, a solidification module is required for solidifying the resist placed on the substrate, but, the details of the solidification module are not limited herein, Similarly, whether gears, chains, transmission rods or other mechanical elements are used to deliver the upper load frame and the lower load frame also are not limited. More important, how the resist is placed on the substrate before the upper load frame being moved toward the lower load frame is not limited. A droplet of resist, especially a resist droplet placed right below the center of the curved elastomer pad, is a good option, but a layer of resist, especially a resist layer distributed mainly below the center of the curved elastomer pad, also is a good option.

Furthermore, some specific examples and related simulations and/or experiments of the present invention are described in the following paragraphs.

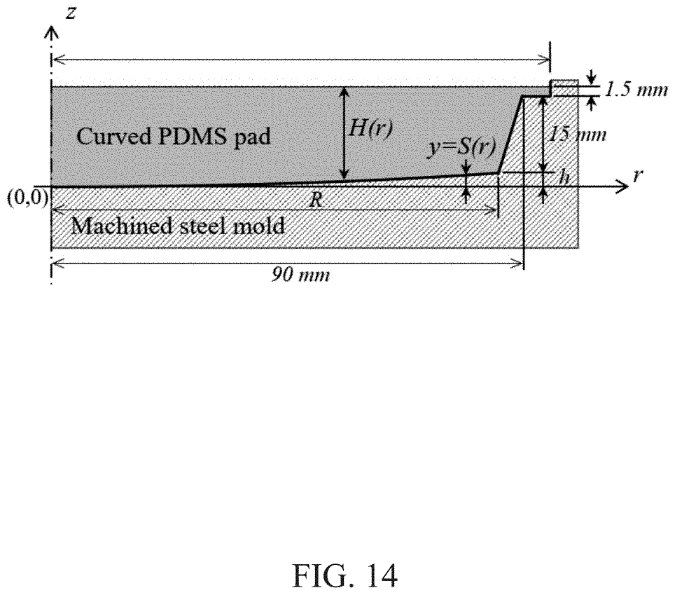

FIG. 14 is related to some exemplary examples that show how the curved elastomer pad is designed and fabricated by using an NC machined steel mold and standard PDMS 184 molding procedures. The curved elastomer pad has one top flat surface to be attached to a quartz plate. On the other side, it is an axial-symmetric and convex surface defined mathematically by a sag height function S(r) in the r-z coordinate system shown in FIG. 14, in which z-axis is the axially symmetrical axis of the curved surface and r the radius. To simplify the design, only conic curves, that is, ellipse, parabola, and hyperbola, are under consideration. The chosen conic curve has to pass two points, the origin point of (0, 0) and the other chosen point with a chosen coordinate of (R, h) in r-z coordinate. The value of R restricts the maximum radius of imprinted area, and h represents the maximum sag height of the curved surface profile. Intuitively, larger h implies higher loading force for completing the imprinting process and also a steeper distribution of compressive pressure ramping down from high pressure in the center toward low pressure at the edge of the mold/substrate.

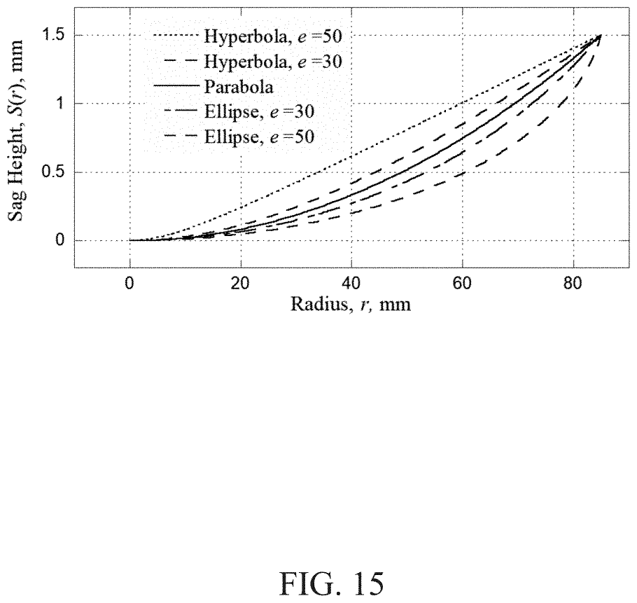

In one exemplary example, the values of R and h were set to 85 mm and 1.5 mm, respectively, and a number of conic curves were generated and displayed in FIG. 15. For a parabolic curve to pass the two points, (0,0) and (85, 1.5) in the r-z coordinate, there is only one choice as depicted in FIG. 15 with the legend of “Parabola”. However, for elliptical and hyperbolic curves, the degree of freedom in the curves is three and therefore there are many different choices. In FIG. 15, the elliptical and hyperbolic curves with an eccentricity (e) of 30 or 50 are displayed, to show the variety of curved surfaces one can use for the surface profile of the elastomer pad. Once the sag height function is chosen, the thickness function of the curved pad, the H(r) shown in FIG. 14, is also determined. When being compressed by the upper quartz plate and lower substrate on a rigid table, as shown in FIG. 13D, the magnitude, the contact area, and the profile of distributed contact pressure are mainly determined by the thickness function and the amounts of movements of the upper and lower loading frames. They are also continuously changing during the courses of imprinting and demolding, which is important in achieving better imprinting and demolding results.

Three of the sag functions displayed in FIG. 15, namely, the hyperbola (e=50), the parabola, and the ellipse (e=50), are actually used to make the machined steel molds by an NC machine. Three curved elastomer pads were then prepared by molding procedures of PDMS 184 as shown in FIG. 14. To experimentally determine the magnitude and spatial distribution of externally exerted contact pressure between PDMS mold and substrate, just for example, an interfacial pressure mapping sensor (such as Model 5151 provided by, Tekscan Inc., MA, USA) and its data acquisition electronics and software (such as I-Scan™ System provided by Tekscan Inc., MA, USA) were used. This pressure mapping sensor is a thin and flexible sheet that can measure and map out the contact pressure between two surfaces. Just for example, it has a measurement area size of 164.8×164.8 mm², in which a square array of 44×44 grid points of pressure measurement is deployed with a center-to-center pitch of 3.8 mm between them. To map out the pressure distribution, a dummy PDMS mold with no surface structures was first prepared and integrated with a metal ring. This PDMS mold and its dovetailed ring is then mounted in the imprinting machine as depicted in FIG. 12. A 6″ glass wafer with a thickness of 1 mm is used as a substrate. The three fabricated elastomer pads were sequentially utilized in the imprinting machine for measuring contact pressure between mold and substrate. The pressure mapping sensor was placed in between the PDMS mold and the glass substrate. To start the imprinting process, the upper loading frame was moving downward to deform the PDMS mold with a deflection distance of 1.5 mm. The lower loading frame was then moving upward until the glass wafer was in touch with the deformed PDMS mold and the pressure sensor started giving a small readout value. From now on, the upper loading frame will remain at its position all the time, while the lower loading frame gradually moved forward so that contact pressure was established and measured. The load cell in the imprinting machining constantly measured the total loading force.

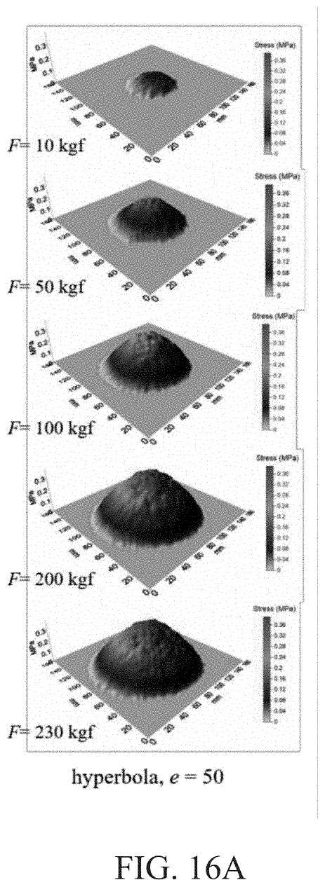

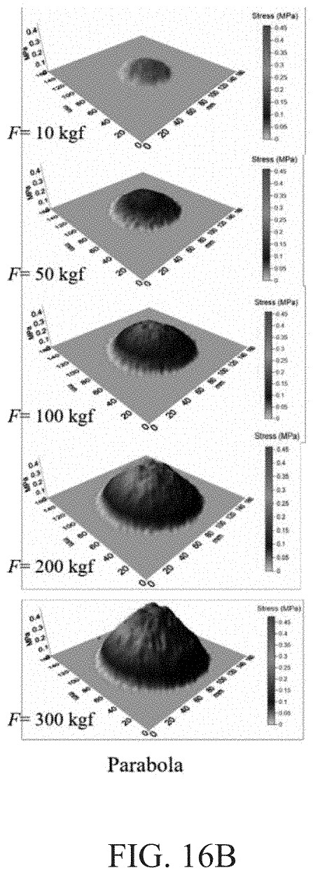

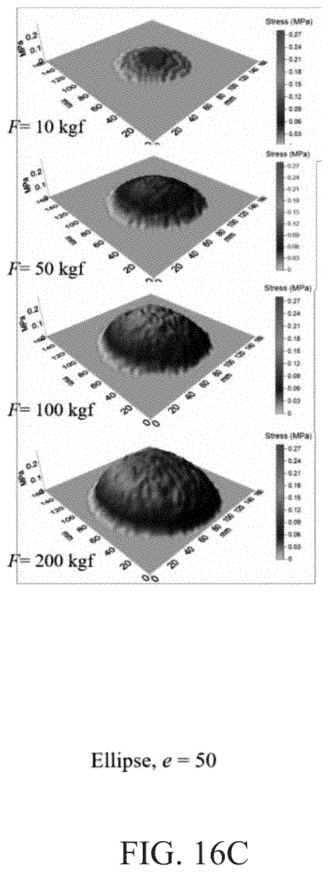

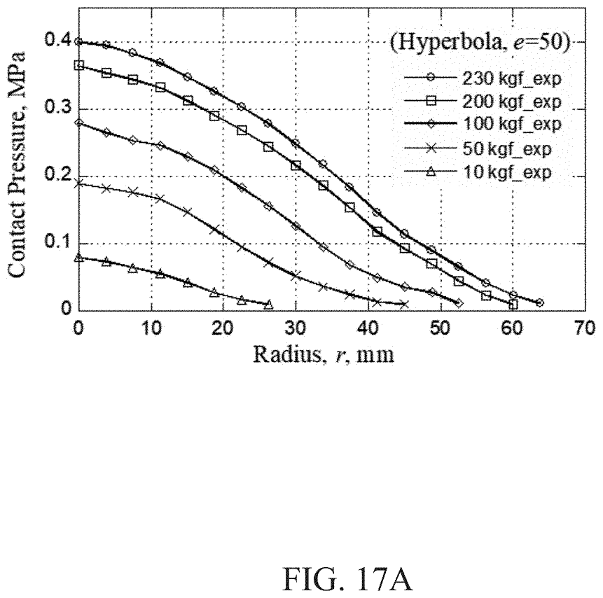

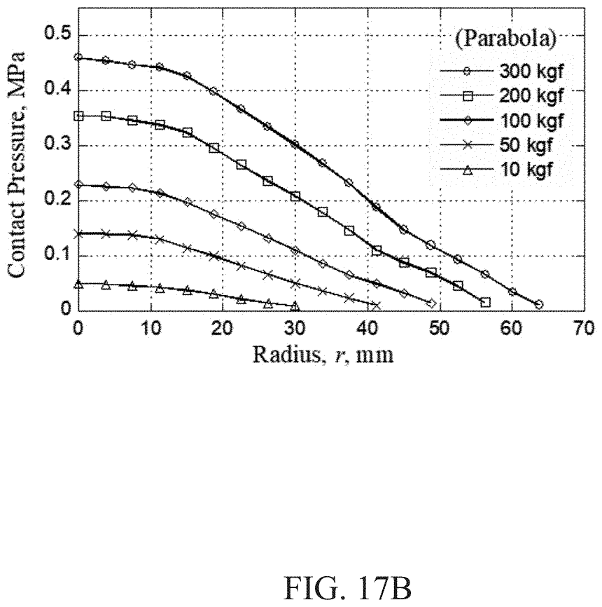

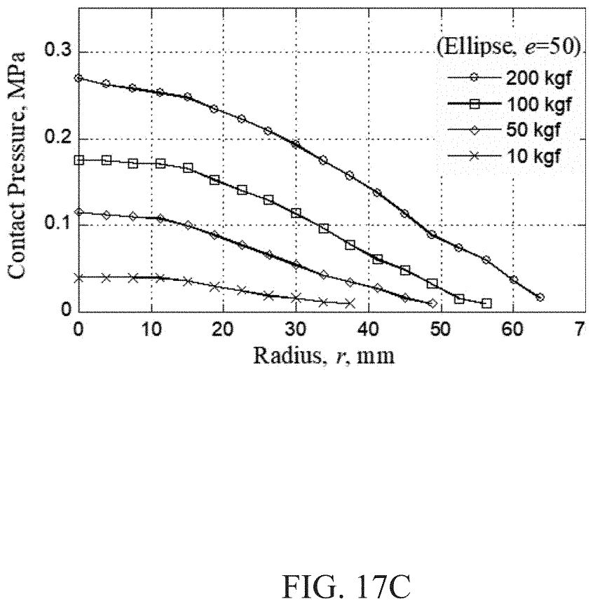

The measurement results are shown in FIG. 16A to 16C for all three types of curved elastomer pad under different loading forces. Since the measured pressure profiles are quite axially symmetric, they are further processed by averaging the measured data along the azimuthal angular direction to yield the dependence of contact pressure on the radius, as shown in FIGS. 17A to 17C. As expected, the interfacial contact pressure all starts from the center and gradually builds up in an axially symmetrical manner. As the upper and lower loading frames are getting closer to squeeze the elastomer pad, the PDMS mold, and the resist, the magnitude of contact force and the radius of contact area are increasing correspondent to increased loading forces. The most important characteristic in these pressure distribution profiles is that there is always a negative pressure gradient radially toward the edge. This is critical for the contact pressure to continuously drive the resist flow, imprint the resist, and maintain a small residual layer thickness during the whole imprinting process. It is also noticed that for the contact area to reach around 5″ or 127 mm in diameter, the maximum loading force needed are 230, 300, and 200 kgf, respectively for the hyperbolic, parabolic, and elliptical profiles, and the peak contact pressure in the center is around 0.4, 0.46, and 0.27 MPa, respectively. This indicates the profile of elastomer cushion pad can effectively influence the contact pressure and its distribution.

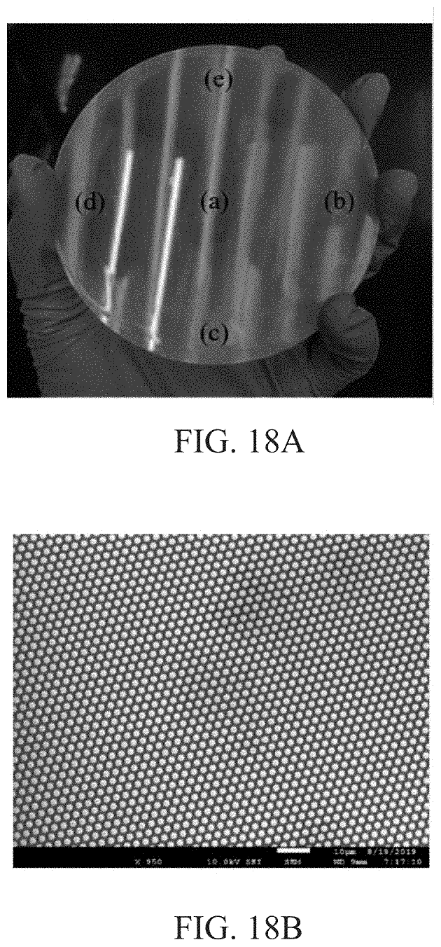

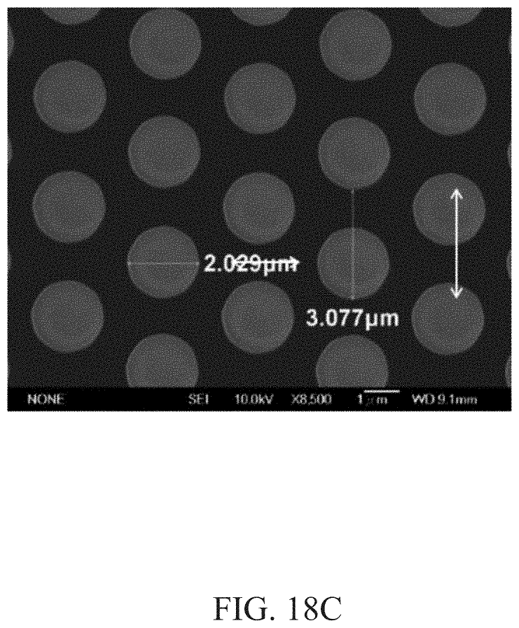

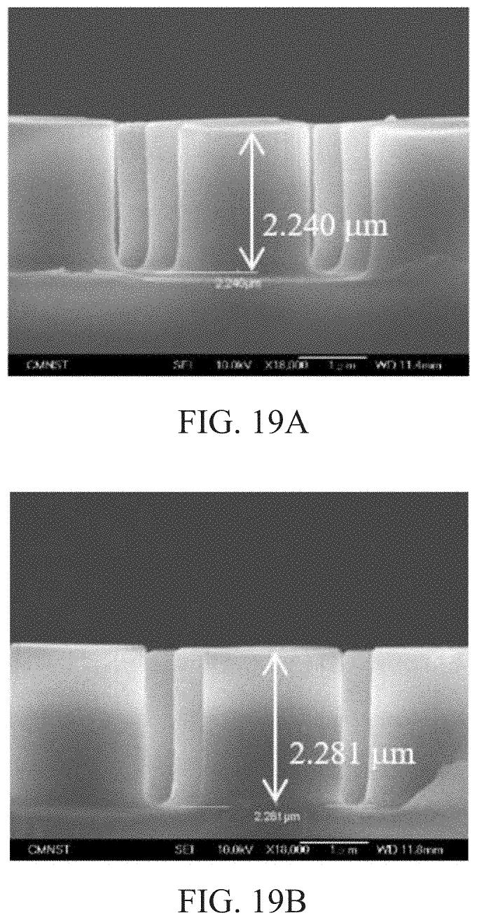

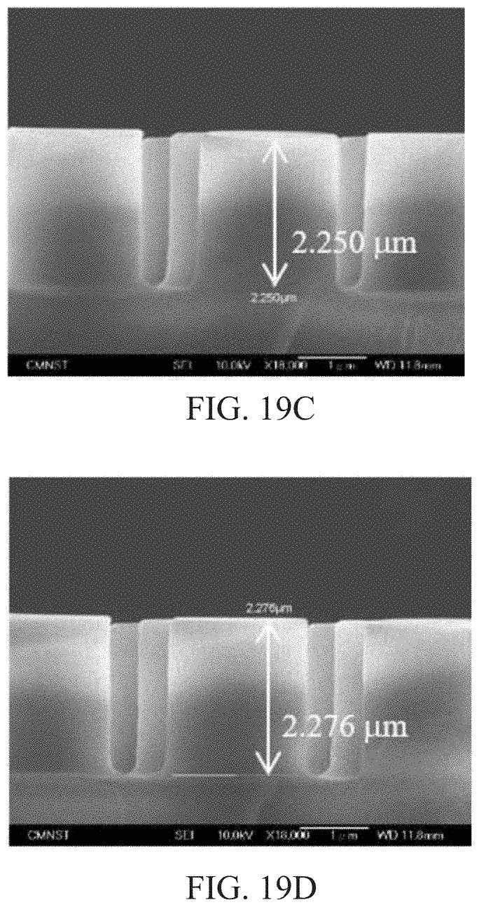

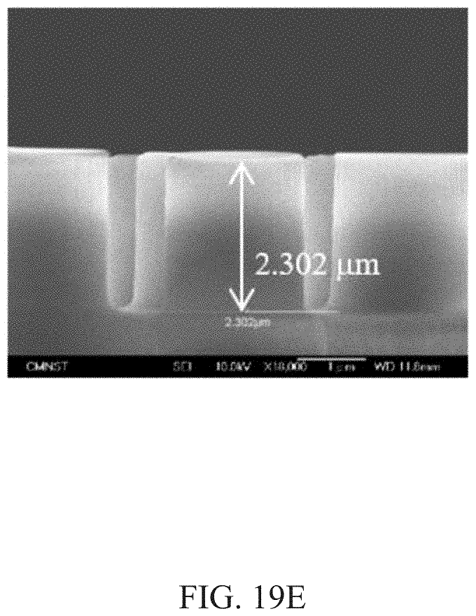

Moreover, to evaluate the droplet spreading imprinting mechanism and its imprinting tool, two nanoimprinting experiments were carried out. The first one is to imprinting an array of micro-pillars with a feature size around 1 to 2 μm and the second one is for arrayed nano-holes with a feature size around 150 nm. Both are carried out on a 4″ glass wafer but using two different UV curable resists. In both experiments, the curved elastomer pad with a parabolic profile shown in FIG. 15 was used. As shown in FIGS. 16B and 17B, it can achieve relatively higher contact pressure and fully cover an area of 4″ in diameter. Furthermore, the parabolic elastomer pad can provide a steeper gradient in the distributed contact pressure, which is beneficial to the spreading of the resist droplet. On the other hand, excessive contact pressure may cause deformation in the surface microstructures on the PDMS mold and should be carefully watched and avoided. For the first micro-scaled imprinting experiment, an 8″ silicon mold with a hexagonal array of micro-pillars was used. The diameter, center-to-center pitch, and height of these micro-pillars are 2 μm, 3 μm, and 2.48 μm, respectively. The silicon mold was fabricated by using conventional photolithography and dry-etching method. The silicon mold was first treated with anti-adhesion and then for replicating a soft PDMS mold. The PDMS mold and its dovetailed ring were mounted in the imprinting machine. A 4″ glass wafer was used as a substrate. To enhance its surface bonding energy, the glass wafer was first treated by O₂ plasma cleaning for 80 seconds under a radio-frequency (RF) power of 150 W and an oxygen flow rate of 20 sccm. A negative-tone photoresist (such as SU8-3050 provided by Micro Chemical Inc., Newton, Mass., USA), was used as the imprinting resist. The SU8 is first mixed with its diluent at a volume ratio of 1:2. A droplet of the SU8 solution with a volume of 80 μL is dropped at the center of glass wafer for imprinting. Similar to the process described previously for measuring contact pressure, the PDMS mold is deformed firstly with a deflection distance of 1.5 mm. After forming an initial contact with the resist droplet, the upper loading frame was fixed in space. Compressive force was then exerted by driving the lower loading frame upward at a speed around 1 mm/min until the 4″ glass wafer is fully imprinted. The measured loading force for obtaining full 4″ wafer imprinting is about 170 kgf. After UV curing of SU8, i.e., after the solidification of SU8, the lower loading frame was then withdrawn at a speed of 0.5 mm/min to slowly separate the PDMS mold from the glass substrate. A photo of the imprinted 4″ wafer is shown in FIG. 18A, and two SEM images with different scales of the imprinted SU8 micro-structures are shown in FIGS. 18B to 18C. The pillar's diameter and pitch are in good agreement with their counterparts in the silicon mold. Cross-sectional SEM images of the imprinted SU8 micro-structures are also shown in FIGS. 19A to 19E which are taken at five different locations roughly indicated in FIG. 18A. The heights of imprinted micro-pillars are around 2.24 to 2.27 μm, which is slightly less than the 2.48 μm in the silicon mold. This is due to the volume shrinkage of PDMS 1001 during thermally curing. Other than that, the imprinted structures are quite uniform in shapes and dimensions across the 4″ wafer. The residual layer thicknesses of these imprinted structures are very small in comparison with the pillar height and are around 60 nm. Based on these SEM images we can conclude the imprinting experiment is quite successful.

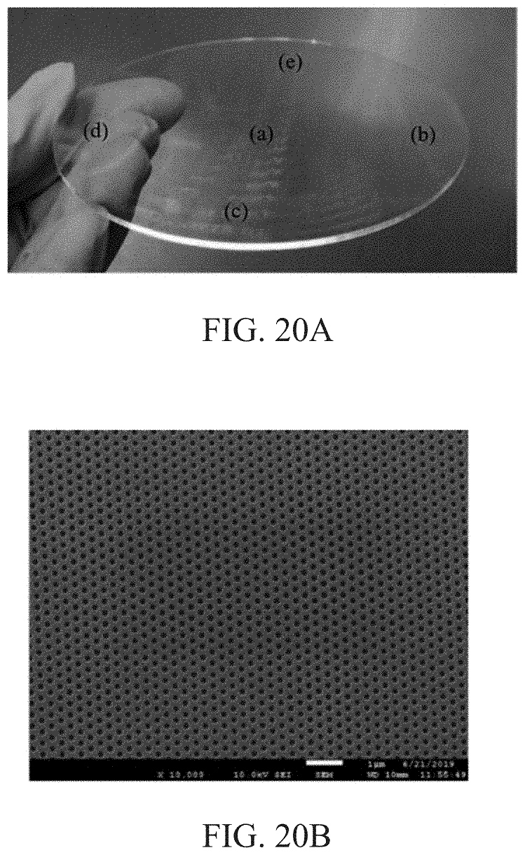

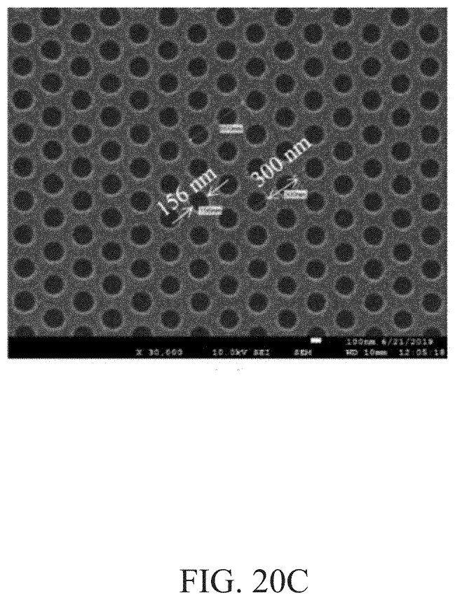

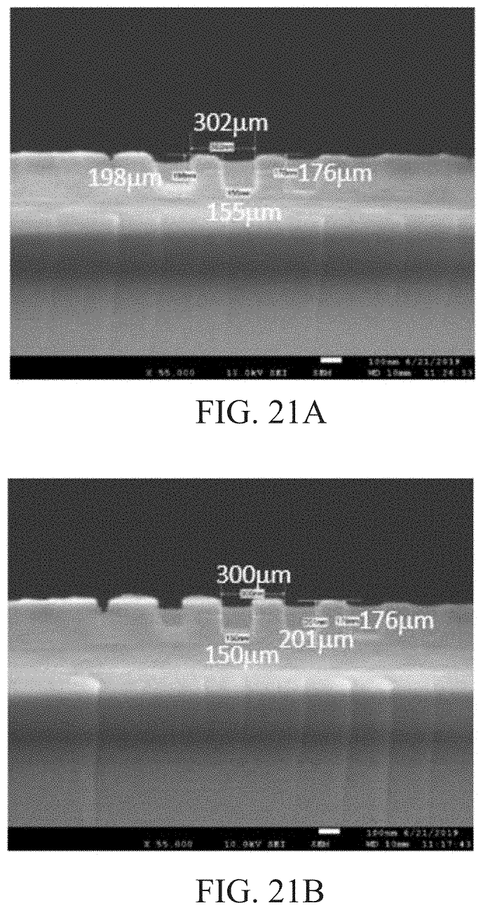

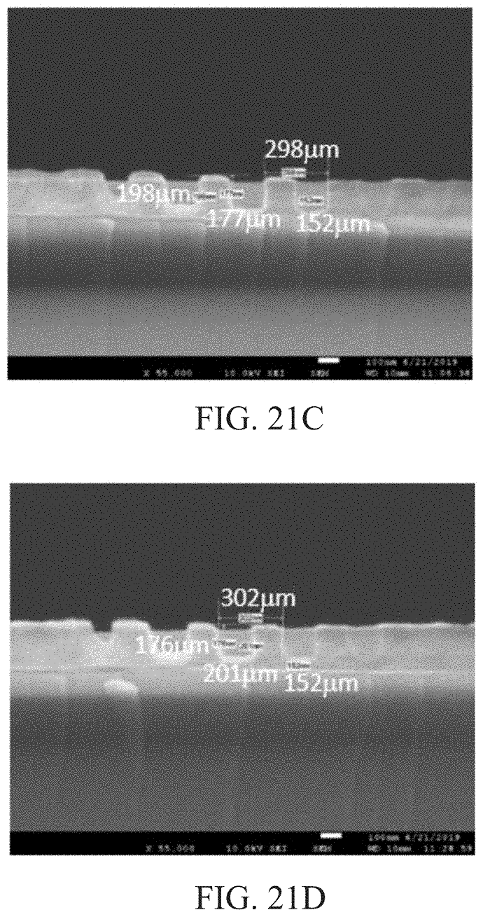

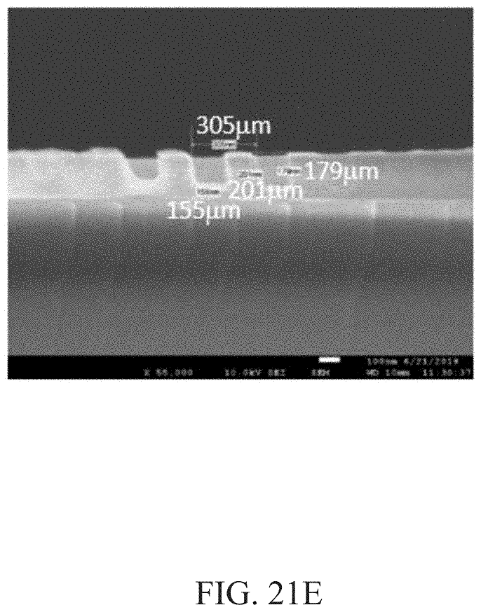

For the nanoimprinting experiment of nano-structures, an 8″ silicon mold with a hexagonal array of nano-scaled holes was used. The diameter, center-to-center pitch, and depth of these nano-holes are 150 nm, 300 nm, and 180 nm, respectively. Again, the goal is to imprinting these arrayed hole-shaped nano-structures on a full 4″ glass wafer. The processes were basically the same as what has been described above for imprinting arrayed micro-pillars. However, since the characteristic feature sizes were significantly reduced, the soft mold was made by first casting a 1 mm thick UV-curable PDMS (such as KER-4690 A/B provided by, Shin-Etsu Chem. Co., Tokyo, Japan) on the silicon mold's surface and then UV cured at a dose of 2000 mJ/cm². This UV-curable PDMS is capable of sub-100 nm pattern replication. After the PDMS 4690 was fully cured, the thermally cured PDMS 1001 was then used to complete the metal-ring-embedded soft imprinting mold. Also, a UV-curable resist (such as the mr-NIL 210 provided by Mirco Resist Technology, Berlin, Germany), is used as the resist for nanoimprinting. After O₂ plasma cleaning, the 4″ glass wafer was first spin-coated with the mr-APS1 (provided by Mirco Resist Technology, Berlin, Germany), which is a primer for mr-NIL 210, and then dried on a hotplate. The primer will promote the surface adhesion to mr-NIL 210. Finally, a droplet of mr-NIL 210 with a volume of 80 μL is dropped on the glass wafer and followed by the imprinting procedures as described above. A number of different total loading forces were tested to minimized the imprinted residual layer thickness. It was found when the loading force reached 380 kgf the minimal residual layer thickness may be achieved. A photo of an imprinted 4″ glass wafer is shown in FIG. 20A. The SEM images of imprinted nano-scaled holes with two different scales are shown in FIGS. 20B to 20C. The diameter and center-to-center pitch of imprinted holes are well-matched with their counterparts in the silicon mold. Cross-sectional SEM images of these imprinted nano-holes are shown in FIGS. 21A to 21E taken at five different locations roughly indicated in FIG. 20A. The hole diameter, hole depth, and residual layer thickness were all measured and listed in Table 1. The diameters and depth are well-matched to their counterparts in the silicon mold and the residual layer thickness is controlled around 21 to 25 nm. For an imprinted depth of 177 nm, this residual layer thickness is quite sufficient for subsequent etching processing.

TABLE 1
Feature of sizes of imprinted nano-holes measured
at five locations roughly indicated in FIG. 20A

| | | | Residual Layer |
|---|---|---|---|
| | Hole Depth | Hole Diameter | Thickness |
| Locations | (nm) | (nm) | (nm) |
| (a) | 176 | 155 | 22 |
| (b) | 176 | 150 | 25 |
| (c) | 177 | 152 | 21 |
| (d) | 176 | 152 | 25 |
| (e) | 179 | 155 | 22 |
| Average | 176.8 | 152.8 | 8.7% |
| Uniformity | 0.85% | 1.64% | 8.7% |

Furthermore, although some embodiments and drawings presented above disclose the situation that the profile transformed into the resist is uniform, i.e., each small undulation of the transformed profile has equivalent dimension, at least has equivalent depth, the invention is not limited by this. Note that the essential mechanism of the invention is transforming the profile of the micro/nano-structure on the surface of the soft mold into the resist on the substrate, wherein the soft mold is deformed to has a curved surface so as to squeeze the resist and imprint micro/nano-structure into the squeezed resist. Hence, by adjusting the details of both the present nanoimprinting method and the present nanoimprinting system, the finally cured resist may have a number of undulations with uniform height distribution or a height distribution inclined from the center portion to the periphery/surrounding portion. Generally speaking, because the curved elastomer pad is protruding in the middle part and the mold is deformed by the mechanical contact with the curved elastomer pad, the resist on the middle portion of the substrate has more mechanical interaction with the mold, resulting in the deeper small undulations therein. Relatively, the resist on the periphery portion of the substrate has less mechanical interaction with the mold, and then resulting in the shallower small undulations therein. However, by adjusting how the soft mold is deformed, such as adjusting how the periphery of the soft mold is pressed after the formation of the initial contact until the imprinted resist is cured, the graduation of the height distribution of these undulations in the cured resist is adjustable, even maybe adjusted to be flat fully.

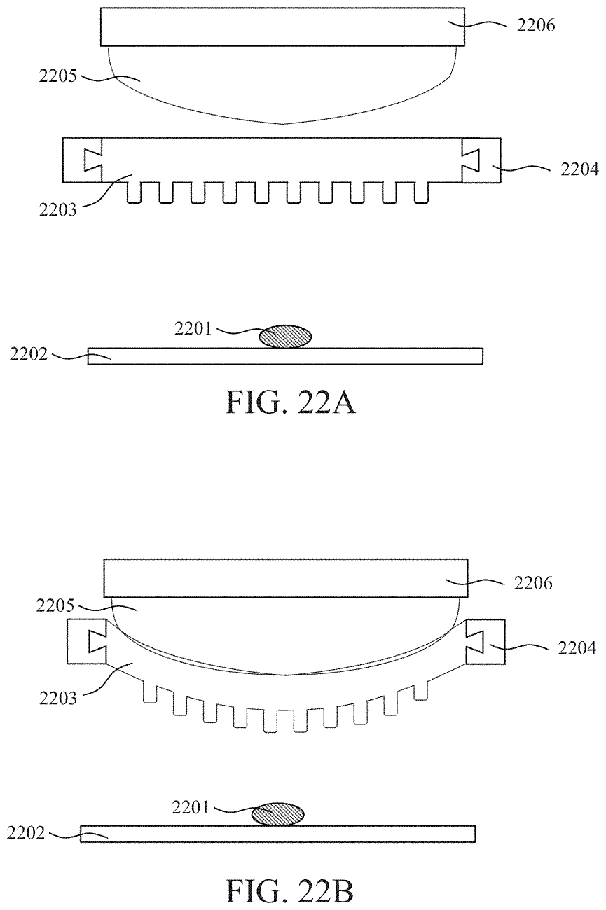

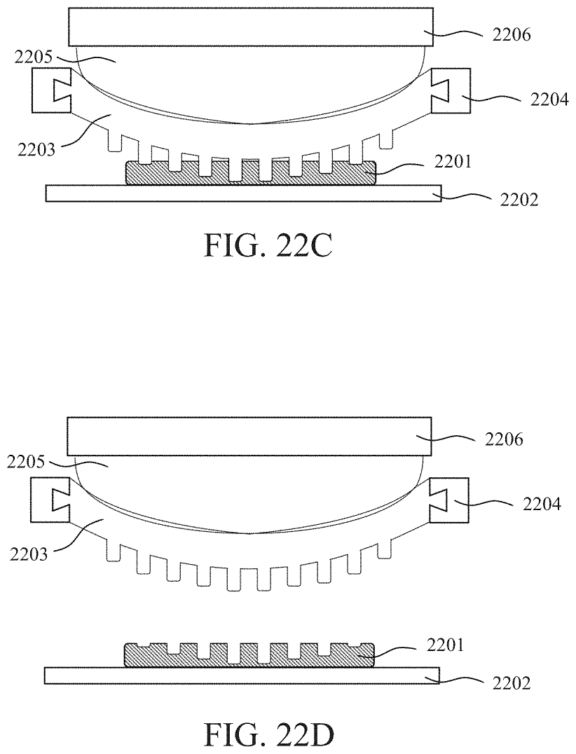

FIG. 22A to 22D show schematically some steps of a specific embodiment wherein an original resist droplet is squeezed and cured to have a non-uniform transformed profile. First of all, as shown in FIG. 22A, a large resist droplet 2201 is disposed on the center portion of a substrate 2202, a soft mold 2203 with a dovetailed ring 2204 is placed above and separated from the resist droplet 2201, and a curved elastomer pad 2205 held by a plate 2206 is positioned above and separated from the soft mold 2203, wherein the surface of the soft mold 2203 facing to the resist droplet 2201 and substrate 2202 has a profile of micro/nano-structure having a number of equivalent small undulations. Then, as shown in FIG. 22B, the curved elastomer pad 2205 and the plate 2206 is driven to mechanically contact with the soft mold 2203 so as to deform the soft mold 2203. After that, as shown in FIG. 22C, the deformed soft mold 2203 and the substrate 2202 are moved to each other such that the resist droplet 2201 is squeezed into a resist layer 2207 therebetween ad then the profile of micro/nano-structure on the soft mold 2203 is transformed non-uniformly into the resist layer 2207. Note that the mechanical contact between the micro/nano-structure on the surface of the soft mold 2203 and the resist layer 2207 is different significantly among different portions of the resist layer 2207, which may be induced by some factors such as the deformation of the soft mold 2203, the height of each small undulation of the micro/nano-structure and the thickness of the resist layer 2207. For the situation shown in FIG. 22C, right after the soft mold 2203 just mechanically contacts with the substrate 2202, i.e., right after the micro/nano-structure on the middle of the soft mold 2203 just touches the center of the top surface of the substrate 2202, the relative movement between the soft mold 2203 and the substrate 2202 is stopped immediately and the dovetailed ring 2204 is not moved anymore (i.e., the soft mold 2203 is not deformed anymore). In this way, the soft mold 2203 is not further deformed and then the mechanical contact between the resist layer 2207 and the soft mold 2203 is distributed non-uniformly over the substrate 2202, which induces automatically the gradual height distribution of these undulations on the resist layer 2207. Finally, as shown in FIG. 22D, the substrate 2202 with the resist layer 2207 is separated from both the soft mold 2203 and the dovetailed ring 2204, and the resist layer 2207 left on the substrate 2202 has a non-uniform profile with deeper small undulations on the center portion and shallower small undulations on the periphery/surrounding portions. Reasonably, by adjusting at least the deformation of the soft mold 2203, the profile of the micro/nano-structure on the soft mold 2203, the amount of the resist droplet 2001, and the thickness of the resist layer 2207 decided by the mechanical contact between the soft mold 2203 and the substrate 2202, the profile of the finally cured resist layer 2207 may be flexibly adjusted. For example, if the deformation of the soft mold 2203 is smaller enough and/or the height of each small undulation of the micro/nano-structure is smaller obviously than the thickness of the resist layer 2207, all small undulations on the finally cured resist layer 2207 may be considered as equivalent. In contrast, if the deformation of the soft mold 2203 is larger enough and/or the height of each small undulation is almost equivalent to the thickness of the resist layer 2207, each small undulation on the finally curd resist layer 2207 may be viewed as having different depth.

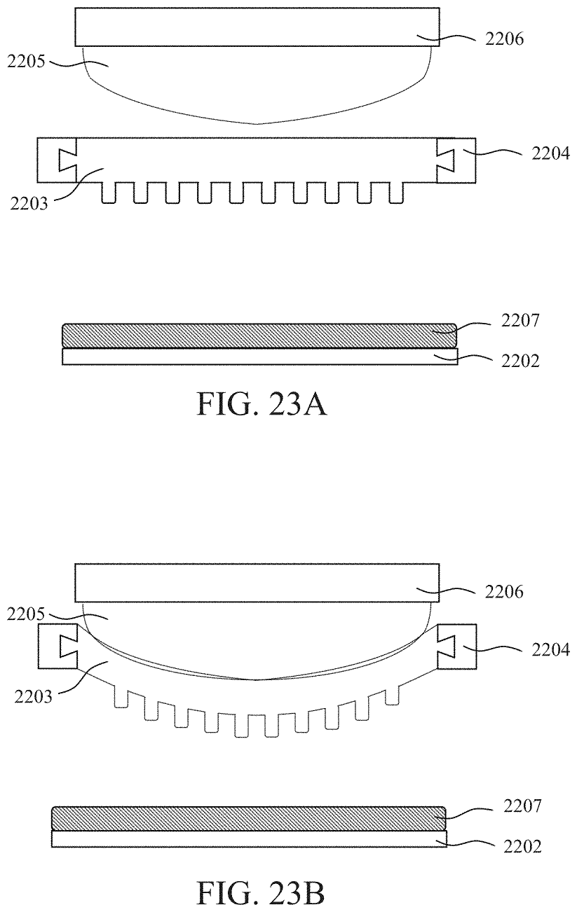

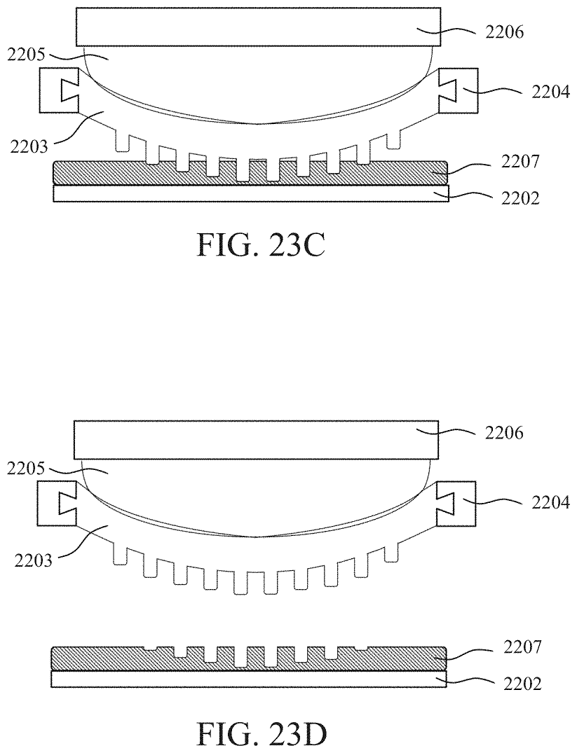

FIGS. 23A to 23D show schematically some step of another specific embodiment wherein an original resist layer is cured to have non-uniform transformed profile. First of all, as shown in FIG. 23A, a resist layer 2301 is formed on both the center and the periphery portions of a substrate 2302, a soft mold 2303 with a dovetailed ring 2304 is placed above and separated from the resist layer 2301, and a curved elastomer pad 2305 held by a plate 2306 is positioned above and separated from the soft mold 2303, wherein the surface of the soft mold 2303 facing to the resist layer 2301 and substrate 2302 has a profile of micro/nano-structure having a number of equivalent small undulations. Then, as shown in FIG. 23B, the curved elastomer pad 2305 and the plate 2306 is driven to mechanically contact with the soft mold 2303 so as to deform the soft mold 2303. After that, as shown in FIG. 23C, the deformed soft mold 2303 and the substrate 2302 are moved to each other such that the resist layer 2301 is squeezed ad then the profile of micro/nano-structure on the soft mold 2303 is transformed non-uniformly into the resist layer 2201. Note that the mechanical contact between the micro/nano-structure on the surface of the mold 2313 and the resist layer 2301 is different significantly among different portions of the resist layer 2301, which may be induced by some factors such as the deformation of the soft mold 2303, the height of each small undulation of the micro/nano-structure and the thickness of the resist layer 2301. For the situation shown in FIG. 23C, right after the soft mold 2303 just mechanically contacts with the substrate 2302, i.e., right after the micro/nano-structure on the middle of the soft mold 2303 just touches the center of the top surface of the substrate 2302, the relative movement between the soft mold 2303 and the substrate 2302 is stopped immediately and the dovetailed ring 2304 is not moved anymore (i.e., the soft mold 2303 is not deformed anyform). In this way, the soft mold 2303 is not further deformed and then the mechanical contact between the resist layer 2301 and the soft mold 2303 is distributed non-uniformly over the substrate 2302, which induces automatically the gradual height distribution of these undulations on the resist layer 2301. Finally, as shown in FIG. 23D, the substrate 2302 with the resist layer 2301 is separated from both the soft mold 2303 and the dovetailed ring 2304, and the resist layer 2301 left on the substrate 2302 has a non-uniform profile with deeper small undulations on the center portion and shallower small undulations on the periphery/surrounding portions. Obviously, the main difference between the two specific embodiments shown on FIGS. 22A to 22D and FIGS. 23A to 23D is how the resist is appeared initially on the substrate: a larger resist droplet dropped thereon or a resist layer deposited thereon. Hence, by adjusting at least the deformation of the soft mold 2303, the profile of the micro/nano-structure on the soft mold 2303, the original amount and the final thickness of the resist layer 2301 decided by the mechanical contact between the soft mold 2303 and the substrate 2302, the profile of the finally cured resist layer 2307 may be flexibly adjusted. Again, if the deformation of the soft mold 2303 is smaller enough and/or the height of each small undulation of the micro/nano-structure is smaller obviously than the thickness of the resist layer 2301, all small undulations on the finally cured resist layer 2301 may be considered as equivalent. In contrast, if the deformation of the soft mold 2303 is larger enough and/or the height of each small undulation is almost equivalent to the thickness of the resist layer 2301, each small undulation on the finally curd resist layer 2301 may be viewed as having different depth.

As a short summary, the invention proposes both a nanoimprinting system and nanoimprinting method for realizing resist spreading imprinting, also a method for making a PDMS mold used in both proposed system and proposed method are proposed. Essentially, the method for making a PDMS mold comprises the following steps in sequence: provides a metal ring with an inner dovetailed groove to form a dovetailed ring, places the dovetailed ring on top of a mother mold, pours a PDMS solution into a cavity defined by the dovetailed ring and the mother mold, thermally cures the liquid PDMS to solidify and form a PDMS mold, and separates the PDMS mold from the mother mold. Essentially, the nanoimprinting system for realizing resist spreading imprinting comprises the following elements: an upper loading frame capable of moving upward and downward, a lower loading frame capable of moving upward and downward, a table positioned between and separated from both loading frames and configured to mount a soft mold, a solidification module configured to solidify the soft mold, an elastomer cushion pad with a convex surface profile and is mechanically connected with the upper loading frame so that it can move vertically, and a substrate configured to be placed on the table which is mechanically connected with the lower loading frame so that it can move vertically, wherein the upper loading frame and the lower loading frame are individually driven. Essentially, the nanoimprinting method for realizing resist spreading imprinting comprises the following steps in sequence: (a) form a resist on a substrate, wherein the substrate is driven by a lower loading frame, wherein a curved elastomer pad is positioned above both the resist and the substrate and driven by an upper loading frame and, wherein a soft mold is positioned between and separated from the curved elastomer pad and both the resist and the substrate, also wherein a solidification module is provided for solidifying the resist. (b) move the upper loading frame toward the soft mold to slightly deform the soft mold downwardly. (c) move both the lower loading frame and the substrate to approach the deformed soft mold until the resist forms an initial contact with the soft mold at its lowest point. (d) move either one or both the upper and the lower loading frame to establish a contact pressure between the soft mold and the substrate and then to imprint the mold's surface profile into the resist. (e) solidify the imprinted resist. And (f) reverse the imprinting movement by withdrawing either or all of upper and lower loading frames away from the soft mold, after the resist being curved. More and more details and variations of the proposed system and both proposed methods may be referred to these contents presented on the previous paragraphs and drawings.

The above-mentioned detailed description aims to specifically illustrate one practicable embodiment of the present invention, but the embodiment is not for limiting the patent scope of the present invention and all equivalent embodiments or modifications made without departing from the spirit of the present invention shall be contained within the patent scope of the present invention. Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

What is claimed is:

1. A nanoimprinting system for realizing resist spreading imprinting, comprising:
an upper loading frame capable of moving upward and downward;
a lower loading frame capable of moving upward and downward;
a table positioned between and separated from both loading frames, configured to mount a resist;
a solidification module, configured to solidify the resist;
an elastomer cushion pad with a convex surface profile and is mechanically connected with the upper loading frame so that it can move vertically;
a soft mold positioned between the resist and elastomer cushion; and
a substrate, configured to be placed on the table which is mechanically connected with the lower loading frame so that it can move vertically;
wherein, the upper loading frame and the lower loading frame are individually driven.

2. The system according to claim 1, wherein the soft mold is a soft PMDS mold that the solidified PMDS material filled into a cavity defined by a dovetailed ring being a metal ring with an inner dovetailed groove, and wherein the soft mold is mounted with a holding fixture through its dovetailed metal ring above the base table.

3. The system according to claim 1, wherein the solidification module has a quartz plate and a planar UV light source, wherein the quartz plate is held by a fixture which is then attached to the upper loading frame through a load cell and the planar UV light source is configured to radiate UV light through the quartz plate, also wherein the quartz plate is positioned above the soft mold when the soft mold is positioned on the table and the elastomer cushion pad is adhered to the quartz plate, wherein the solidification module has a heat source chosen from a group consist of the following: the light bulbs, the thermoelectric wires and any combination thereof.

4. The system according to claim 1, wherein the substrate is firmly attached to a vacuum plate embedded in the table.

5. The system according to claim 1, wherein the resist is placed on the center of the substrate right beneath the soft mold before the upper loading frame and the lower loading frame being driven to let the curved elastomer pad contact with the resist.

6. The system according to claim 5, the resist is in a droplet form of the resist material or in a layer form of the resist material.

7. A nanoimprinting method for realizing resist spreading imprinting, comprising:
(a) forming a resist on a substrate, wherein the substrate is driven by a lower loading frame, wherein a curved elastomer pad is positioned above both the resist and the substrate and driven by an upper loading frame and, wherein a soft mold is positioned between and separated from the curved elastomer pad and both the resist and the substrate, also wherein a solidification module is provided for solidifying the resist;
(b) moving the upper loading frame toward the soft mold to slightly deform the soft mold downwardly;
(c) moving both the lower loading frame and the substrate to approach the deformed soft mold until the resist forms an initial contact with the soft mold at its lowest point;
(d) moving either one or both the upper and the lower loading frame to establish a contact pressure between the soft mold and the substrate and then to imprint the mold's surface profile into the resist;
(e) solidifying the imprinted resist; and
(f) reversing the imprinting movement by withdrawing either or all of upper and lower loading frames away from the soft mold, after the resist being curved.

8. The method according to claim 7, further comprising using a soft PMDS mold as the soft mold, wherein the soft PMDS mold has the solidified PMDS material filled in a cavity defined by a dovetailed ring being a metal ring with an inner dovetailed groove, wherein the curved elastomer pad is made of PDMS 184 by its standard molding procedures using a steel mold with a pre-designed concave surface machined by a numerical control machine.

9. The method according to claim 7, further comprising applying pressure at the interface between the soft mold and the substrate by the movement between the upper loading frame and the lower loading frame so as to drive the resist flow, close the gap between the soft mold and the substrate, enlarge the contact area therebetween, and then imprint soft mold's surface profile into the resist.

10. The method according to claim 7, further comprising controlling the speed of the imprinting process by the movement of both loading frames with a pre-programmed time history in terms of displacement or velocity, wherein the magnitude and the distribution of the applied contact pressure are strongly determined by the thickness profile of the curved elastomer pad through its compressive deformation and stain during imprinting.

11. The method according to claim 7 further comprising using a UV light source and a quartz plate to form the solidification module, wherein the curved elastomer pad and the UV light source is separated by the quartz while the curved elastomer pad is adhered on the quartz plate, and wherein the UV light source radiates an UV light energy through the quartz plate and the cured elastomer pad to solidify the imprinted resist.

12. The method according to claim 11, wherein one side of the curved elastomer pad is a top flat surface to be attached to the quartz plate and another side of the curved elastomer pad is an axial-symmetric and convex surface.

13. The method according to claim 12, wherein the axial-symmetric and convex surface is defined by a sag height function S(r) in the r-z coordinate that z-axis is the axially symmetrical axis of the curved surface and r is the radius.

14. The method according to claim 13, wherein the sag height function S(r) is a conic curve passing through the origin point of (0,0) and the chosen point of (R,h) in the r-z coordinate and chosen from a group consist of the following: ellipse, parabola and hyperbola.

15. The method according to claim 7, further comprising one or more of the following:
controlling the movements of either or all of loading frames by using a computer;
monitors the applied loading force through a load cell posited between the upper loading frame and the curved elastomer pad;
adjusting one or more of the following factors to achieve better imprinting result: the initial displacement of deformed mold, the thickness profile of the curved elastomer pad being used, and the subsequent movements of both upper and lower loading frames during imprinting and demolding stages.

16. The method according to claim 7, further comprising determining the magnitude and spatial distribution of externally exerted contact pressure between the mold and the substrate by using an interfacial pressure mapping sensor and its data acquisition electronics and software, wherein the pressure mapping sensor is a thin and flexible sheet, wherein a dummy mold with no surface structure is used, and wherein the sensor is placed in between the mold and the substrate.

17. The method according to claim 12, wherein the maximum loading force needed are 230 kgf, 300 kgf and 200 kgf and the peak contact pressure in the center is around 0. MPa, 0.46 MPa and 0.27 MPa for the molds having hyperbolic profile, parabolic profile and elliptical profiles respectively when the contact area between the mold and the substrate reaches around 127 nm in diameter.

18. The method according to claim 12, wherein the resist on the middle portion of the substrate has deeper small undulations therein and wherein the resist on the periphery portion of the substrate has the shallower small undulations.

19. The method according to claim 12, further comprising stopping immediately the relative movement between the soft mold and the substrate and not deforming the soft mold any more right after the soft mold just mechanically contacts with the substrate.

20. The method according to claim 12, further comprising flexibly adjusting the profile of the finally cured resist layer by adjusting at least the deformation of the mold, the profile of the micro/nano-structure on the mold, the amount of the resist, and the thickness of the imprinted resist layer.
